(19) United States
(12) Patent Application Publication
(10) Pub. No.: US 2026/0107833 A1
(43) Pub. Date: Apr. 16, 2026

(54) SEMICONDUCTOR PACKAGE AND METHODS OF MANUFACTURING THE SAME

(71) Applicant: Taiwan Semiconductor Manufacturing Company, Ltd., Hsinchu (TW)

(72) Inventors: Ping-Yin Hsieh, Hsinchu City (TW); Chih-Wei Wu, Yilan County (TW); Ying-Ching Shih, Hsinchu City (TW)

(73) Assignee: Taiwan Semiconductor Manufacturing Company, Ltd., Hsinchu (TW)

(21) Appl. No.: 18/912,533

(22) Filed: Oct. 10, 2024

(51) Int. Cl. H01L 25/16; H01L 21/50; H01L 23/00; H01L 23/367; H01L 23/498; H01L 23/538

(52) U.S. Cl. CPC H10W 90/00; H10W 40/22; H10W 70/611; H10W 90/401; H10W 90/701; H10W 95/00; H10W 72/07352; H10W 72/321; H10W 90/734

(57) ABSTRACT

A semiconductor package includes a substrate, a bridge die, a first sub-package and a second sub-package, and a plurality of connectors. The bridge die is adhered on a first side of the substrate by an adhesive. The first sub-package and the second sub-package are disposed on the substrate and electrically coupled to the substrate and the bridge die, where the bridge die is disposed between the first sub-package and the substrate. The plurality of connectors are disposed on a second side of the substrate, the first side is opposite to the second side, where the plurality of connectors is electrically coupled to the substrate.

### BACKGROUND

Developments in shrinking sizes of semiconductor devices and electronic components make the integration of more devices and components into a given volume possible and lead to high integration density of various semiconductor devices and/or electronic components. Integrated circuit applications currently have increasingly more functions built therein, and are thus formed to be increasingly larger.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1, FIG. 4, FIG. 5, FIG. 6, FIG. 7, FIG. 8, and FIG. 9 are schematic cross-sectional views or plane views of various stages in manufacturing a semiconductor package in accordance with some embodiments of the disclosure.

FIG. 2 and FIG. 3 are schematic, cross-sectional and enlarged views respectively showing various embodiments of a bonding configuration of a bridge die, an adhesive and a circuit substrate in a semiconductor package in accordance with the disclosure.

FIG. 10 through FIG. 11 are respectively a schematic cross-sectional view of a semiconductor package in accordance with some alternative embodiments of the disclosure.

FIG. 12 is a schematic cross-sectional view of a semiconductor package in accordance with some embodiments of the disclosure.

FIG. 13 through FIG. 14 are respectively a schematic cross-sectional view of a semiconductor package in accordance with some alternative embodiments of the disclosure.

FIG. 15 through FIG. 16 are respectively a schematic plane view of a semiconductor package in accordance with some alternative embodiments of the disclosure.

FIG. 17 is a schematic cross-sectional view of an application of a semiconductor package in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor package including a circuit substrate, two or more sub-packages each having a semiconductor die (or chip) and a memory die (or module) and being disposed over the circuit substrate and next to each other, and a bridge die (or chip) disposed over the circuit substrate via an adhesive and electrically coupling to the two or more sub-packages, where the sub-packages each have two groups of connectors with different dimensions for allowing electrical connections between the sub-packages and the circuit substrate via the connectors of large dimensions and between the sub-packages and the bridge die (or chip) via the connectors of small dimensions. With such bridge die (or chip), no photo stitching is needed in the manufacture of the semiconductor package having a large scale structure (e.g., 8X reticle), and there is no change in the circuit/routing design of the circuit substrate. In addition, with such configuration, the warpage of the semiconductor package having the large scale structure (e.g., 8X reticle) can be well-controlled, and the wafer area utilization can maintain the same or be further improved. The manufacture of such semiconductor package is compatible to the current and/or advanced manufacturing processes.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

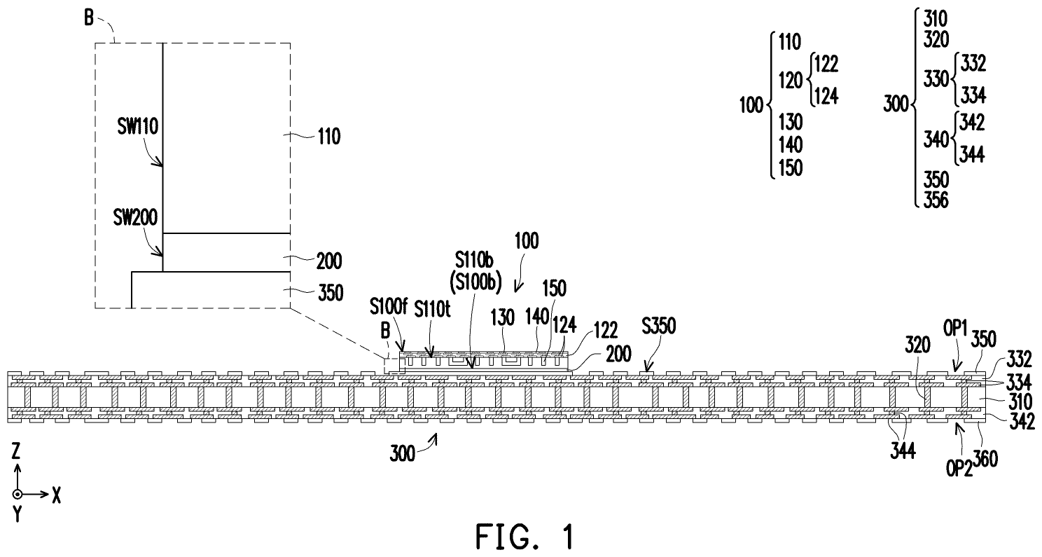

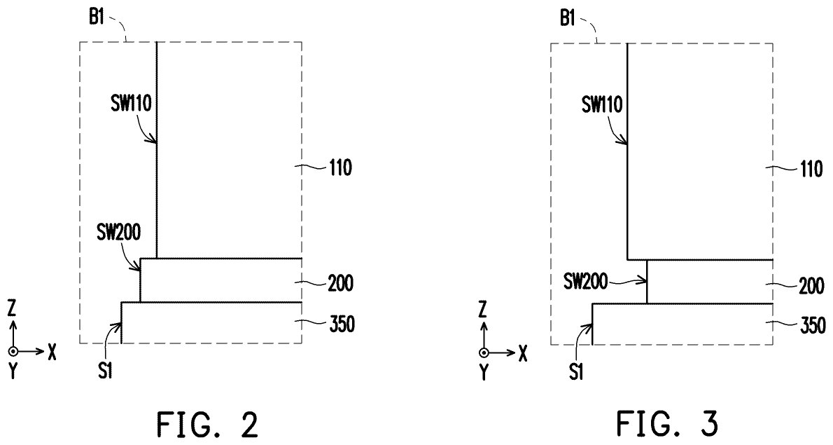

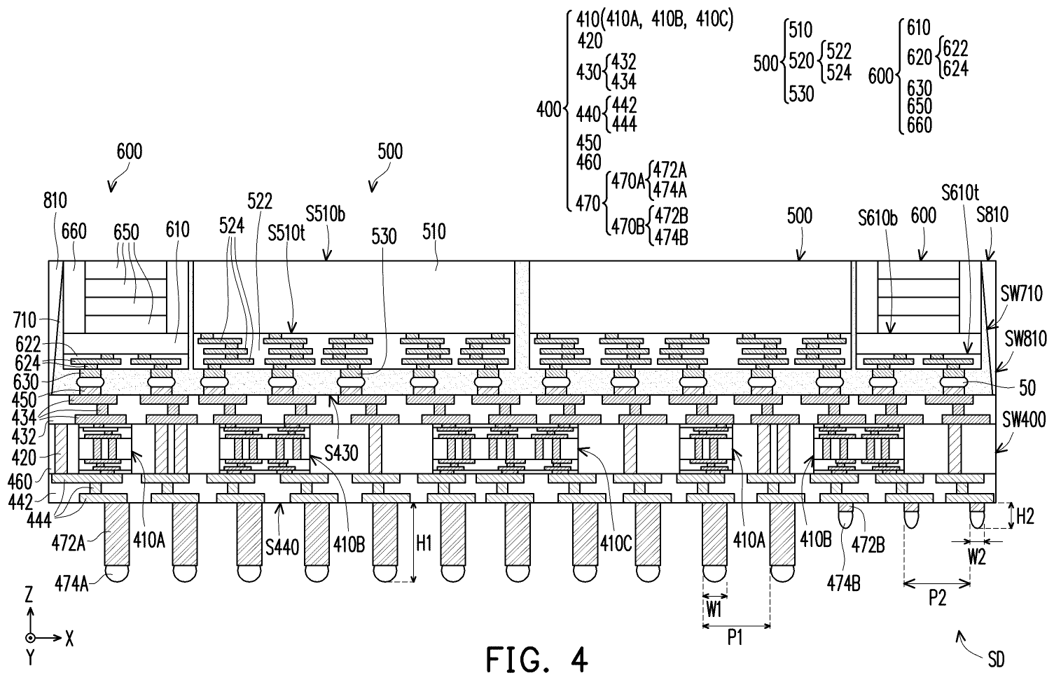

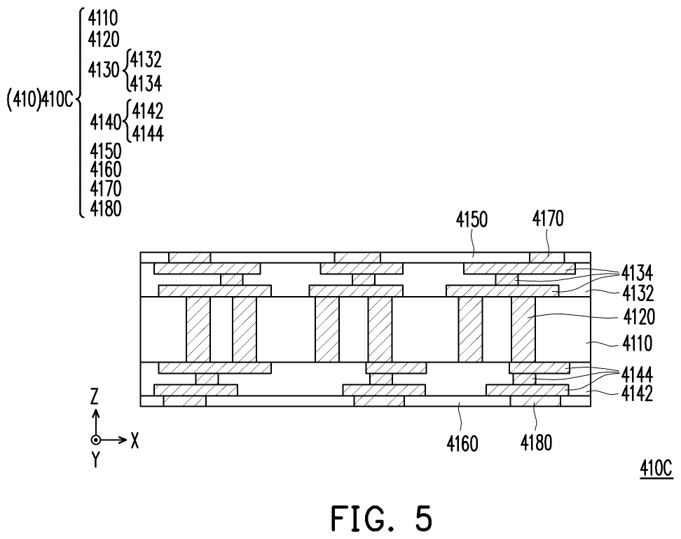

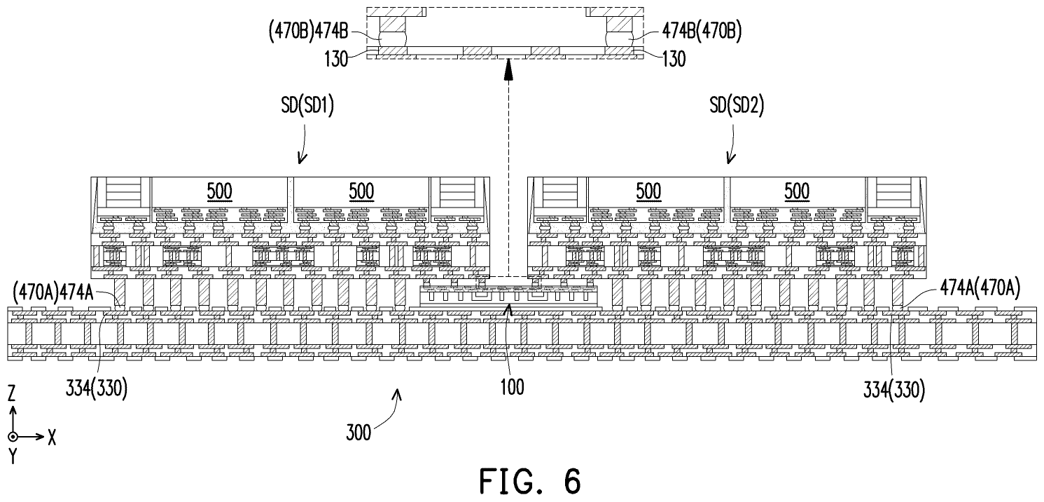

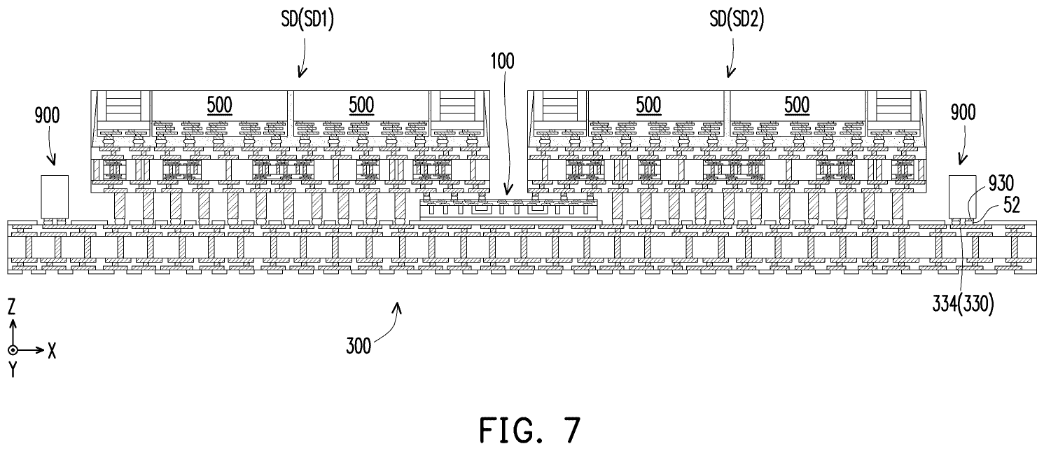

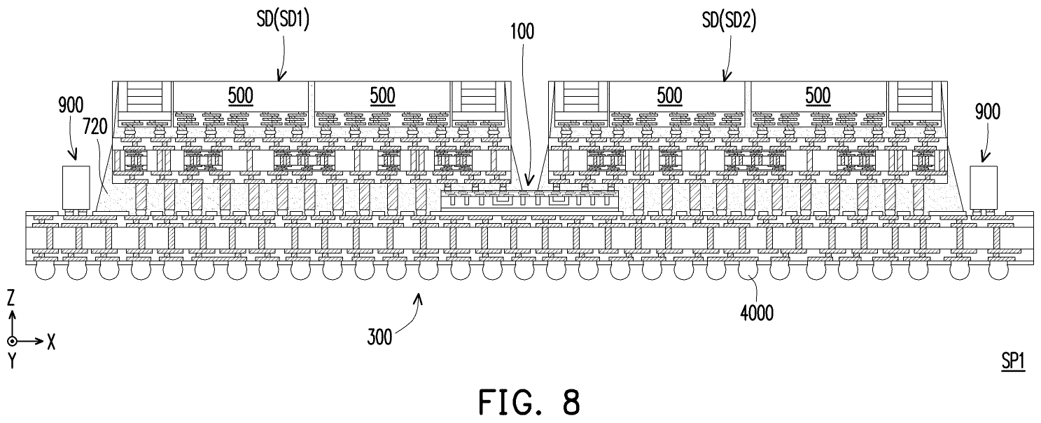

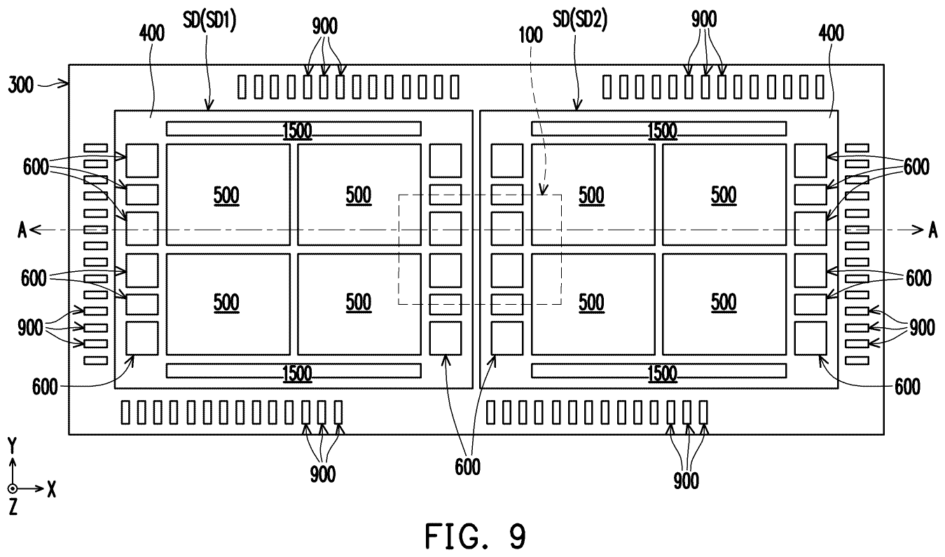

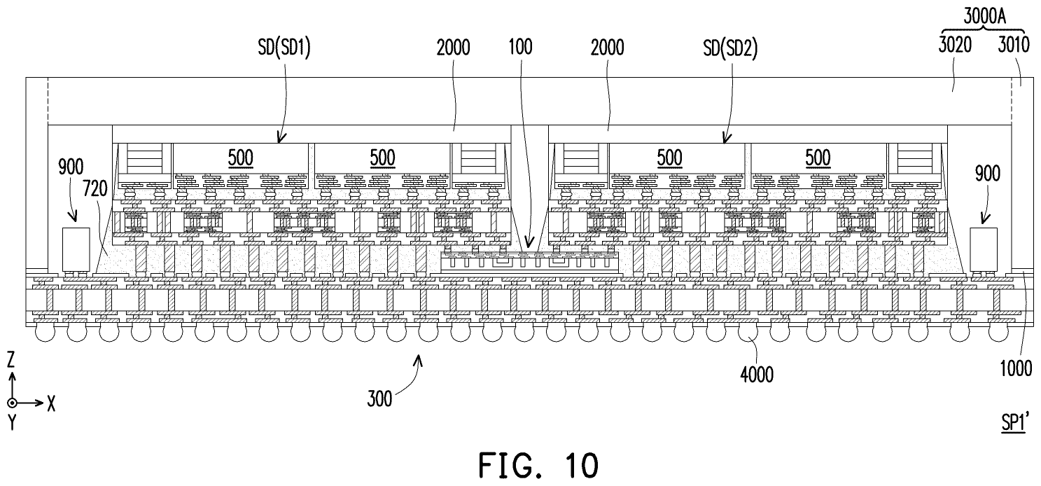

FIG. 1, FIG. 4, FIG. 5, FIG. 6, FIG. 7, FIG. 8, and FIG. 9 are schematic cross-sectional views or plane views of various stages in manufacturing a semiconductor package (e.g., SP1) in accordance with some embodiments of the disclosure, where the cross-sectional views of FIG. 1, FIG. 5, FIG. 6, FIG. 7 and FIG. 8 are taken along a line AA′ depicted in the plane view of FIG. 9, and the cross-section of FIG. 4 shows a bridge die (e.g., 410) included in a sub-package (e.g., SD) of the semiconductor package (e.g., SP1). FIG. 2 and FIG. 3 are schematic, cross-sectional and enlarged views respectively showing various embodiments of a bonding configuration of a bridge die, an adhesive and a circuit substrate, which are outlined by a dashed-box B depicted in FIG. 1 (e.g., a dashed-box B1 in FIG. 2 and/or a dashed-box B2 in FIG. 3). FIG. 10 through FIG. 11 are respectively a schematic cross-sectional view of a semiconductor package (e.g., SP1′ or SP1″) in accordance with some alternative embodiments of the disclosure.

Referring to FIG. 1, in some embodiment, a circuit substrate 300 is provided, where the circuit substrate 300 includes a substrate 310, a plurality of through vias 320, a redistribution circuit structure 330, a redistribution circuit structure 340, and dielectric layers 350, 360. In addition to or alternatively, the redistribution circuit structure 330 and/or the redistribution circuit structure 340 may be omitted. The circuit substrate 300 may include a substrate 310, a plurality of through vias 320, a redistribution circuit structure 330, and dielectric layers 350, 360. Alternatively, the circuit substrate 300 may include a substrate 310, a plurality of through vias 320, a redistribution circuit structure 340, a and dielectric layers 350, 360. Or, the circuit substrate 300 may include a substrate 310, a plurality of through vias 320, and dielectric layers 350, 360. The circuit substrate 300 may be referred to as a substrate.

In some embodiments, the substrate 310 is a wafer, such as a bulk semiconductor substrate, a silicon-on-insulator (SOI) substrate, a multi-layered semiconductor substrate, or the like. The semiconductor material of the substrate 310 may be silicon, germanium; a compound semiconductor including silicon carbide, gallium arsenic, gallium phosphide, indium phosphide, indium arsenide, and/or indium antimonide; an alloy semiconductor including silicon germanium (SiGe), GaAsP, AlInAs, AlGaAs, GaInAs, GaInP, and/or GaInAsP; or combinations thereof. The alloy SiGe may be formed over a silicon substrate. The SiGe substrate may be strained. In an alternative embodiment, other substrates, such as multi-layered or gradient substrates, may also be used. The substrate 310 may be doped or undoped. The substrate 310 may include a wide variety of devices (not shown) (also referred to as semiconductor devices) formed therein. The devices may include active devices, passive devices, or a combination thereof. The devices may include integrated circuits devices. The devices may include transistors, capacitors, resistors, diodes, photodiodes, fuse devices, jumpers, inductors, or other similar devices. The functions of the devices may include memory, processors, sensors, amplifiers, power distribution, input/output circuitry, or the like. The devices each may be referred to as a semiconductor component. Alternatively, the substrate 310 may be substantially free of active devices and passive devices, and merely provide routing functions.

In some embodiments, the through vias 320 are formed in the substrate 310 and penetrating through the substrate 310. The through vias 320 may be sometimes referred to as through-substrate-vias or through-silicon-vias as the substrate 310 is a silicon substrate. The through vias 320 may be formed by forming recesses in the substrate 310 (by, for example, etching, milling, laser techniques, a combination thereof, and/or the like) and depositing a conductive material in the recesses. The conductive material may be formed by an electro-chemical plating process, a chemical vapor deposition (CVD), an atomic layer deposition (ALD), a physical vapor deposition (PVD), a combination thereof, and/or the like. Examples of conductive materials are copper, tungsten, aluminum, silver, gold, a combination thereof, and/or the like. An optional thin dielectric material may be formed in the recesses, such as by using an oxidation technique, to separate the substrate 310 and the through vias 320. A thin barrier layer may be conformally formed in the recesses, such as by CVD, ALD, PVD, thermal oxidation, a combination thereof, and/or the like, to separate the substrate 310 and the optional thin dielectric material. The barrier layer may comprise a nitride or an oxynitride, such as titanium nitride, titanium oxynitride, tantalum nitride, tantalum oxynitride, tungsten nitride, a combination thereof, and/or the like. Excess conductive material and barrier layer is removed from an illustrated top surface of the substrate 310 by, for example, chemical mechanical polishing (CMP) process. Thus, the through vias 320 may comprise a conductive material, a thin barrier layer between the conductive material and the substrate 310 and an optional dielectric layer between the thin barrier layer and the substrate 310. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc. The number of the through vias 320 is not limited to the drawings of the disclosure, and may be designated and selected based on the demand and design layout.

In some embodiments, the redistribution circuit structure 330 is formed on the illustrated top surface (not labeled) of the substrate 310, and is electrically connected to the substrate 310. In certain embodiments, the redistribution circuit structure 330 includes a dielectric structure 332 and one or more metallization layers 334 arranged therein for providing routing functionality. For example, the dielectric structure 332 includes one or more dielectric layers, such that the dielectric layers and the metallization layer 334 are sequentially formed, and one metallization layer 334 is sandwiched between two dielectric layers. As shown in FIG. 1, portions of an illustrated top surface of a topmost layer of the metallization layers 334 may be respectively exposed by a topmost portion (e.g., a topmost dielectric layer) of the dielectric structure 332, and portions of an illustrated bottom surface of a bottommost layer of the metallization layers 334 may be respectively exposed by a bottommost portion (e.g., a bottommost dielectric layer) of the dielectric structure 332; however, the disclosure is not limited thereto. For example, the illustrated top surface (not labeled) of the topmost layer of the metallization layers 334 is substantially level with an illustrated top surface (not labeled) of the topmost dielectric layer of the dielectric structure 332. In such case, the illustrated top surface (not labeled) of the topmost layer of the metallization layers 334 may be substantially coplanar to the illustrated top surface (not labeled) of the topmost dielectric layer of the dielectric structure 332. On the other hand, for example, the illustrated bottom surface (not labeled) of the bottommost layer of the metallization layers 334 is substantially level with an illustrated bottom surface (not labeled) of the bottommost dielectric layer of the dielectric structure 332. In such case, the illustrated bottom surface (not labeled) of the bottommost layer of the metallization layers 334 may be substantially coplanar to the illustrated bottom surface (not labeled) of the bottommost dielectric layer of the dielectric structure 332.

In some embodiments, a redistribution circuit structure 340 is formed on the illustrated bottom surface (not labeled) of the substrate 310, and is electrically connected to the substrate 310. In certain embodiments, the redistribution circuit structure 340 includes a dielectric structure 342 and one or more metallization layers 344 arranged therein for providing routing functionality. For example, the dielectric structure 342 includes one or more dielectric layers, such that the dielectric layers and the metallization layer 344 are sequentially formed, and one metallization layer 344 is sandwiched between two dielectric layers. As shown in FIG. 1, portions of an illustrated top surface of a topmost layer of the metallization layers 344 may be respectively exposed by a topmost portion (e.g., a topmost dielectric layer) of the dielectric structure 342, and portions of an illustrated bottom surface of a bottommost layer of the metallization layers 344 may be respectively exposed by a bottommost portion (e.g., a bottommost dielectric layer) of the dielectric structure 342; however, the disclosure is not limited thereto. For example, the illustrated top surface (not labeled) of the topmost layer of the metallization layers 344 is substantially level with an illustrated top surface (not labeled) of the topmost dielectric layer of the dielectric structure 342. In such case, the illustrated top surface (not labeled) of the topmost layer of the metallization layers 344 may be substantially coplanar to the illustrated top surface (not labeled) of the topmost dielectric layer of the dielectric structure 342. On the other hand, for example, the illustrated bottom surface (not labeled) of the bottommost layer of the metallization layers 344 is substantially level with an illustrated bottom surface (not labeled) of the bottommost dielectric layer of the dielectric structure 342. In such case, the illustrated bottom surface (not labeled) of the bottommost layer of the metallization layers 344 may be substantially coplanar to the illustrated bottom surface (not labeled) of the bottommost dielectric layer of the dielectric structure 342.

The material of the dielectric structures 332, 342 may include silicon oxide, silicon nitride, silicon oxy-nitride, or any other suitable dielectric materials, and may be formed by deposition or the like. The metallization layers 334, 344 may be or include patterned copper layers or other suitable patterned metal layers, and may be formed by electroplating or deposition. However, the disclosure is not limited thereto. Alternatively, the metallization layers 334, 344 may be formed by single or dual-damascene method. The numbers of the metallization layers and the dielectric layers included in each of the redistribution circuit structures 330, 340 is not limited to the drawings of the disclosure, and may be designated and selected based on the demand and design layout.

The through vias 320 may be connected to the portions of the illustrated bottom surface of the bottommost layer of the metallization layers 334 respectively exposed by the bottommost dielectric layer of the dielectric structure 332 and the portions of the illustrated top surface of the topmost layer of the metallization layers 344 respectively exposed by the topmost dielectric layer of the dielectric structure 342, as shown in FIG. 1. In other words, the redistribution circuit structure 330 is electrically connected to the redistribution circuit structure 340 through the through vias 320. The redistribution circuit structures 330, 340 independently may further be electrically connected to the active and/or passive devices in the substrate 310 (if any) by direct contacts therebetween. In some embodiments, through the redistribution circuit structures 330 and/or 340, the through vias 320 are electrically coupled to the active and/or passive devices in of the substrate 310 (if any).

In some embodiments, the dielectric layer 350 is formed on the redistribution circuit structure 330, where the redistribution circuit structure 330 is disposed between the substrate 310 and the dielectric layer 350 and between the through vias 320 and the dielectric layer 350. As shown in FIG. 1, portions of the redistribution circuit structure 330 may be exposed by a plurality of openings OP1 formed in the dielectric layer 350. For example, the portions of the illustrated top surface of the topmost layer of the metallization layers 334 respectively exposed by the topmost dielectric layer of the dielectric structure 332 are further accessibly revealed by the openings OP1 formed in the dielectric layer 350 for electrical connections to later-formed components. In some embodiments, the dielectric layer 360 is formed on the redistribution circuit structure 340, where the redistribution circuit structure 340 is disposed between the substrate 310 and the dielectric layer 360 and between the through vias 320 and the dielectric layer 360. As shown in FIG. 1, portions of the redistribution circuit structure 340 are exposed by a plurality of openings OP2 formed in the dielectric layer 360. For example, the portions of the illustrated bottom surface of the bottommost layer of the metallization layers 344 respectively exposed by the bottommost dielectric layer of the dielectric structure 342 are further accessibly revealed by the openings OP2 formed in the dielectric layer 360 for electrical connections to later-formed components.

An optional seed layer (not shown) may be formed before forming the bonding pads 352 and after the formation of the dielectric layers 362 so to facilitate the formation of the bonding pads 352. In some embodiments, the bonding pads 352 and the dielectric layer 362 may be formed by, but not limited to, forming a blanket layer of dielectric material over the redistribution circuit structure 330; patterning the dielectric material blanket layer to form the dielectric layer 362 having a plurality of opening holes (not labeled) penetrating through the dielectric layer 362 and accessibly revealing portions of the illustrated top surface of the exposed topmost layer of the metallization layers 334; optionally forming a blanket layer of seed layer material over the dielectric layer 342, the seed layer material blanket layer extending into the opening holes to line the opening holes and in contact with the exposed portions of the illustrated top surface of the exposed topmost layer of the metallization layers 334; forming a blanket layer of a conductive material over the seed layer material blanket layer and to fill the opening holes; patterning the conductive material blanket layer to form the bonding pads 352; using the bonding pads 352 as etching mask to pattern the seed layer material blanket layer and form a respective optional seed layer. In some embodiments, the optional seed layer is a metal layer, which may be a single layer or a composite layer comprising a plurality of sub-layers formed of different materials. In some embodiments, the optional seed layer comprises a titanium layer and a copper layer over the titanium layer, or two titanium layers and a cupper layer sandwiched between the two titanium layers. The optional seed layer may be formed using, for example, sputtering or the like. Similarly, optional seed layers (not shown) may be adapted to facilitate the formation of the metallization layers 334, if needed. The disclosure is not limited thereto.

Thereafter, a bridge die 100 may be provided and placed over the circuit substrate 300, as shown in FIG. 1. In some embodiments, the bridge die 100 is adhered onto the circuit substrate 300 through an adhesive 200. For example, the adhesive 200 includes a die attach film (DAF) or the like. As shown in FIG. 1, an non-active (or rear) side S110b of the bridge die 100 is adhered to an illustrated top surface S350 of the dielectric layer 350 of the circuit substrate 300, thus there is no directly electrical connection (such as a direct metal-to-metal contact) between the bridge die 100 and the circuit substrate 300, in some embodiments.

In some embodiments, the bridge die 100 includes a substrate 110 having an active side S110t and the non-active side S110b opposite to the active side S110t along a direction Z, an interconnect structure 120 disposed on the active side S110t of the substrate 110, a plurality of conductive vias 130 disposed on and electrically coupled to the interconnect structure 120, a dielectric layer 140 disposed on the interconnect structure 120 and laterally covering the conductive vias 130, and a plurality of conductive pillars 150 embedded inside the substrate 110 and electrically coupled to the interconnect structure 120, where the conductive vias 130 are electrically coupled to the conductive pillars 150 through the interconnect structure 120. As shown in FIG. 1, the conductive vias 130 may be accessibly revealed by the dielectric layer 140 for electrical connections to later-formed components. In some embodiments, illustrated top surfaces of the conductive vias 130 are substantially level with an illustrated top surface of the dielectric layer 140. That is, the illustrated top surfaces of the conductive vias 130 are substantially coplanar to the illustrated top surface of the dielectric layer 140, for example.

In some embodiments, the substrate 110 is a silicon substrate. Alternatively, the substrate 110 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, the interconnect structure 120 includes a dielectric structure 122 (including one or more inter-dielectric layers) and one or more patterned conductive layers 124 stacked alternately. For examples, the inter-dielectric layers are silicon oxide layers, silicon nitride layers, silicon oxy-nitride layers, or dielectric layers formed by other suitable dielectric materials, and are formed by deposition or the like. For examples, the patterned conductive layers 124 are patterned copper layers or other suitable patterned metal layers, and are formed by electroplating or deposition. However, the disclosure is not limited thereto. Alternatively, the patterned conductive layers 124 may be formed by a single or dual-damascene method. The number of the inter-dielectric layers and the number of the patterned conductive layers 124 may be less than or more than what is depicted in FIG. 1, and may be selected and/or designated depending on the demand and/or design layout; the disclosure is not specifically limited thereto. In some embodiments, the interconnect structure 120 is formed in a back-end-of-line (BEOL) process. In certain embodiments, as shown in FIG. 1, the patterned conductive layers 124 are sandwiched between the inter-dielectric layers of the dielectric structure 122, where a surface of the outermost layer of the patterned conductive layers 124 is exposed by an outermost layer of the inter-dielectric layers of the dielectric structure 122 to connect to later formed component(s) for electrical connection(s), and a surface of an innermost layer of the patterned conductive layers 124 is exposed by an innermost layer of the inter-dielectric layers of the dielectric structure 122 and electrically connected to the conductive pillars 150 in the substrate 110.

In some embodiments, the conductive vias 130 are formed on the interconnect structure 120 and over the substrate 110, and sidewalls of the conductive vias 130 are wrapped around by the dielectric layer 140. In some embodiments, as shown in FIG. 1, the conductive vias 130 each penetrate through the dielectric layer 140 to physically contact the surface of the outermost layer of the patterned conductive layers 124 exposed by the outermost layer of the inter-dielectric layers of the dielectric structure 122. Through the interconnect structure 120, the conductive vias 130 are electrically connected to the conductive pillars 150 in the substrate 110. For simplification, only twelve conductive vias 130 are presented in FIG. 1 in the bridge die 100 for illustrative purposes, however it should be noted that more or less conductive vias 130 may be formed; the disclosure is not limited thereto.

In some embodiments, as shown in FIG. 1, the dielectric layer 140 is formed on the interconnect structure 120, where parts of the interconnect structure 120 exposed by the conductive vias 130 are covered by and in contact with the dielectric layer 140. As shown in FIG. 1, the illustrated top surface of the dielectric layer 140 includes a substantially planar surface (e.g., the outermost surface), for example. In certain embodiments, the outermost surface of the dielectric layer 140 is leveled and may have a high degree of planarity and flatness, which is beneficial for the later-formed layers/elements. In some embodiments, the dielectric layer 140 includes a polyimide (PI) layer, a polybenzoxazole (PBO) layer, a silicon dioxide based (non-organic) layer or other suitable polymer (or organic) layer, and is formed by deposition or the like. The disclosure is not limited thereto. The disclosure does not specifically limit a thickness of the dielectric layer 140 as long as the dielectric layer 140 can maintain its high degree of planarity and flatness. In the disclosure, the illustrated top surfaces of the conductive vias 130 and the illustrated top surface of the dielectric layer 140 together may be referred to as a front (or active) side S100f of the bridge die 100, and the surface S110b of the substrate 110 may be referred to as a back (or non-active) side S100b of the bridge die 100.

In some embodiments, the conductive vias 130 are formed by photolithography, plating, photoresist stripping processes or any other suitable method. The plating process may include an electroplating plating, an electroless plating, or the like. For example, the conductive vias 130 is formed by, but not limited to, forming a mask pattern (not shown) covering the dielectric layer 140 with opening holes (not shown) corresponding to the surface of the outermost layer of the patterned conductive layers 124 exposed by the outermost layer of the inter-dielectric layers of the dielectric structure 122, patterning the dielectric layer 140 to form contact openings (not shown) therein for exposing the surface of the outermost layer of the patterned conductive layers 124 exposed by the outermost layer of the inter-dielectric layers of the dielectric structure 122, forming a metallic material to fill the opening holes formed in the mask pattern and the contact openings formed in the dielectric layer 140 to form the conductive vias 130 by electroplating or deposition, and then removing the mask pattern. The dielectric layer 140 may be patterned by an etching process, such a dry etching process, a wet etching process, or the combination thereof. The mask pattern may be removed by acceptable ashing process and/or photoresist stripping process, such as using an oxygen plasma or the like. In one embodiment, the material of the conductive vias 130 includes a metal material such as copper or copper alloys, or the like.

In some embodiments, in a vertical projection on the surface S110t of the substrate 110 along the (stacking) direction Z of the substrate 110, the interconnect structure 120 and the dielectric layer 140, the conductive vias 130 may independently be in a circle-shape, an ellipse-shape, a triangle-shape, a rectangle-shape, or the like. The shape of the conductive vias 130 is not limited in the disclosure. The shape and number of the conductive vias 130 may be selected and/or designated depending on the demand and/or design layout, and may be adjusted by changing the shape and number of the contact openings formed in the dielectric layer 140.

Alternatively, the conductive vias 130 may be formed by, but not limited to, forming a first mask pattern (not shown) covering the dielectric layer 140 with first opening holes (not shown) corresponding to the surface of the outermost layer of the patterned conductive layers 124 exposed by the outermost layer of the inter-dielectric layers of the dielectric structure 122, patterning the dielectric layer 140 to form the contact openings (not shown) therein for exposing the surface of the outermost layer of the patterned conductive layers 124 exposed by the outermost layer of the inter-dielectric layers of the dielectric structure 122, removing the first mask pattern, conformally forming a metallic seed layer over the dielectric layer 140, forming a second mask pattern (not shown) covering the metallic seed layer with second opening holes (not shown) exposing the contact openings formed in the dielectric layer 140, forming a metallic material to fill the second opening holes formed in the second mask pattern and the contact openings formed in the dielectric layer 140 by electroplating or deposition, removing the second mask pattern, and then removing the metallic seed layer not covered by the metallic material to form the conductive vias 130.

In some embodiments, the metallic seed layer is referred to as a metal layer, which includes a single layer or a composite layer comprising a plurality of sub-layers formed of different materials. In some embodiments, the metallic seed layer includes titanium, copper, molybdenum, tungsten, titanium nitride, titanium tungsten, combinations thereof, or the like. For example, the metallic seed layer may include a titanium layer and a copper layer over the titanium layer. The metallic seed layer may be formed using, for example, sputtering, PVD or the like.

In some embodiments, for the bridge die 100, a sidewall SW110 of the substrate 110, a sidewall of the interconnect structure 120 and a sidewall of the dielectric layer 140 are substantially aligned with each other in the direction Z and together constitute a sidewall of the bridge die 100. In other words, a projection of the adhesive 200 is completely overlapped with a projection of the substrate 110 along the direction Z on the X-Y plane.

As shown in FIG. 1, the sidewall SW110 of the substrate 110 is aligned with a sidewall SW200 of the adhesive 200, for example. However, the disclosure is not limited thereto; alternatively, the sidewall SW110 of the substrate 110 may not be aligned with the sidewall SW200 of the adhesive 200 (see FIG. 2 and FIG. 3). In an alternative embodiment as shown in FIG. 2, the sidewall SW110 of the substrate 110 is protruding away from the sidewall SW200 of the adhesive 200, where a projection of the substrate 110 is within a projection of the adhesive 200 along the direction Z on the X-Y plane. In such alternative embodiment, the projection of the substrate 110 is completely within the projection of the adhesive 200 along the direction Z on the X-Y plane. In another alternative embodiment as shown in FIG. 3, the sidewall SW110 of the substrate 110 is indent from the sidewall SW200 of the adhesive 200, where a projection of the substrate 110 spans beyond a projection of the adhesive 200 along the direction Z on the X-Y plane. In such alternative embodiment, the projection of the adhesive 200 is completely within the projection of the substrate 110 along the direction Z on the X-Y plane.

Referring to FIG. 4 through FIG. 5 in conjunction with FIG. 9, a plurality of sub-packages SD is provided and placed over the circuit substrate 300. Only two sub-packages SD are shown in the cross-sectional view of FIG. 4 and only four sub-packages SD are shown in the plane view of the FIG. 9 for illustrative purposes, however the number of the sub-packages SD is not limited to the drawings of the disclosure, and may be selected and designated depending on the demand and the design layout. As shown in FIG. 4, each sub-package SD includes an interposer 400, a plurality of semiconductor dies 500 disposed on and electrically coupled to the interposer 400, a plurality of semiconductor dies 600 disposed on and electrically coupled to the interposer 400 and laterally next to the semiconductor dies 500, an optional underfill 710 disposed in gaps between the interposer 400 and the semiconductor dies 500, between the interposer 400 and the semiconductor dies 600 and between the semiconductor dies 500 and 600, and an insulating encapsulation 810 laterally encapsulating the semiconductor dies 500 and 600 and the optional underfill 710 and covering the interposer 400 exposed by the semiconductor dies 500 and 600 and the optional underfill 710, in some embodiments. For example, the semiconductor dies 500 are electrically coupled to each other through the interposer 400, the semiconductor dies 600 are electrically coupled to each other through the interposer 400. For example, the semiconductor dies 500 are electrically coupled to the semiconductor dies 600 through the interposer 400. The number of the semiconductor dies 500 and the number of semiconductor dies 600 are not limited to the drawings of the disclosure, which can be selected and/or designated depending on the demand and the design layout.

In some embodiments, as shown in FIG. 4, each of the semiconductor dies 500 includes a semiconductor substrate 510 having a surface S510t (may referred to as an active or front surface) and a surface S510b (may referred to as a non-active or rear surface) opposite to the surface S510t, an interconnect structure 520 disposed over the surface S510t of the semiconductor substrate 510, a plurality of conductive vias 530 disposed over and electrically coupled to the interconnect structure 520, where the interconnect structure 520 is disposed between the semiconductor substrate 510 and the conductive vias 530. In some embodiments, the semiconductor substrate 510 is a silicon substrate including active devices (e.g., transistors and/or memories such as N-type metal-oxide semiconductor (NMOS) and/or P-type metal-oxide semiconductor (PMOS) devices, or the like) and/or passive devices (e.g., resistors, capacitors, inductors or the like) formed therein. In some embodiments, such active devices and passive devices are formed in a front-end-of-line (FEOL) process. In an alternative embodiment, the semiconductor substrate 510 is a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto. Alternatively, the semiconductor substrate 510 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, the interconnect structure 520 includes a dielectric structure 522 (including one or more inter-dielectric layers) and one or more patterned conductive layers 524 stacked alternately. For examples, the inter-dielectric layers are silicon oxide layers, silicon nitride layers, silicon oxy-nitride layers, or dielectric layers formed by other suitable dielectric materials, and are formed by deposition or the like. For examples, the patterned conductive layers 524 are patterned copper layers or other suitable patterned metal layers, and are formed by electroplating or deposition. However, the disclosure is not limited thereto. Alternatively, the patterned conductive layers 524 may be formed by a single or dual-damascene method. The number of the inter-dielectric layers of the dielectric structure 522 and the number of the patterned conductive layers 524 may be less than or more than what is depicted in FIG. 4, and may be selected and/or designated depending on the demand and/or design layout; the disclosure is not specifically limited thereto. In some embodiments, the interconnect structure 520 is formed in a BEOL process. In certain embodiments, as shown in FIG. 4, the patterned conductive layers 524 are sandwiched between the inter-dielectric layers of the dielectric structure 522, where a surface of the outermost layer of the patterned conductive layers 524 is exposed by an outermost layer of the inter-dielectric layers of the dielectric structure 522 to connect to later formed component(s) for electrical connection (e.g. with the conductive vias 530), and a surface of an innermost layer of the patterned conductive layers 524 is exposed by an innermost layer of the inter-dielectric layers of the dielectric structure 522 and electrically connected to the active devices and/or passive devices included in the semiconductor substrate 510.

In some embodiments, the conductive vias 530 are formed on the interconnect structure 520 and over the semiconductor substrate 510. In some embodiments, as shown in FIG. 4, the conductive vias 530 each physically contact the surface of the outermost layer of the patterned conductive layers 524 exposed by the outermost layer of the inter-dielectric layers of the dielectric structure 522. Through the interconnect structure 520, the conductive vias 530 are electrically connected to the active devices and/or passive devices included in the semiconductor substrate 510. In some embodiments, the conductive vias 530 in physical contact with the interconnect structure 520 are extended away from the outermost surface of the interconnect structure 520. For simplification, only five conductive vias 530 are presented in each semiconductor die 500 of FIG. 4 for illustrative purposes, however it should be noted that more than five conductive vias 530 may be formed; the disclosure is not limited thereto.

In some embodiments, the conductive vias 530 are formed by photolithography, plating, photoresist stripping processes or any other suitable method. The plating process may include an electroplating plating, an electroless plating, or the like. For example, the conductive vias 530 is formed by, but not limited to, forming a mask pattern (not shown) covering the interconnect structure 520 with opening holes (not shown) corresponding to the surface of the outermost layer of the patterned conductive layers 524 exposed by the outermost layer of the inter-dielectric layers of the dielectric structure 522, forming a metallic material to fill the opening holes formed in the mask pattern to form the conductive vias 530 by electroplating or deposition, and then removing the mask pattern. The mask pattern may be removed by acceptable ashing process and/or photoresist stripping process, such as using an oxygen plasma or the like. In one embodiment, the material of the conductive vias 530 includes a metal material such as copper or copper alloys, or the like.

In some embodiments, in a vertical projection on the surface S510t of the semiconductor substrate 510 along the (stacking) direction Z of the semiconductor substrate 510, the interconnect structure 520 and the conductive vias 530, the conductive vias 530 may independently be in a circle-shape, an ellipse-shape, a triangle-shape, a rectangle-shape, or the like. The shape of the conductive vias 530 is not limited in the disclosure. The shape and number of the conductive vias 530 may be selected and/or designated depending on the demand and/or design layout.

Alternatively, the conductive vias 530 may be formed by, but not limited to, conformally forming a metallic seed layer over the interconnect structure 520, forming a mask pattern (not shown) covering the metallic seed layer with opening holes (not shown) corresponding to the surface of the outermost layer of the patterned conductive layers 524 exposed by the outermost layer of the inter-dielectric layers of the dielectric structure 522, forming a metallic material to fill the opening holes formed in the mask pattern by electroplating or deposition, removing the mask pattern, and then removing the metallic seed layer not covered by the metallic material to form the conductive vias 530. In some embodiments, the metallic seed layer is referred to as a metal layer, which includes a single layer or a composite layer comprising a plurality of sub-layers formed of different materials. In some embodiments, the metallic seed layer includes titanium, copper, molybdenum, tungsten, titanium nitride, titanium tungsten, combinations thereof, or the like. For example, the metallic seed layer may include a titanium layer and a copper layer over the titanium layer. The metallic seed layer may be formed using, for example, sputtering, PVD or the like.

In some embodiments, the semiconductor dies each 500 further includes a seal ring (not shown) embedded in the interconnect structure 520 to surround the patterned conductive layers 524 inside the dielectric structure 522. Owing to the seal ring, the interconnect structure 520 (e.g., of the dielectric structure 522 and the patterned conductive layers 524) is protected from the physical damages and/or the moistures or hydrogen attacks for the environment. In some embodiments, for each semiconductor die 500, a sidewall of the semiconductor substrate 510 and a sidewall of the interconnect structure 520 are substantially aligned with each other in the direction Z and together constitute a sidewall of the semiconductor die 100.

It is appreciated that, in some embodiments, the semiconductor dies 500 independently described herein may be referred to as a semiconductor chip or an integrated circuit (IC). In some embodiments, the semiconductor dies 500 independently is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor dies 500 independently may be or include a digital chip, an analog chip or a mixed signal chip. The semiconductor dies 500 independently may be a chip or an IC of combination-type, such as a WiFi chip simultaneously including both of a RF chip and a digital chip.

In alternative embodiments, the semiconductor dies 500 independently is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc. ; a combination thereof; or the like.

In some embodiments, the types of all of the semiconductor dies 500 are identical. In alternative embodiments, the types of some of the semiconductor dies 500 are different from each other, while the types of some of the semiconductor dies 500 are identical types. In further alternative embodiments, the types of all of the semiconductor dies 500 are different. In some embodiments, the sizes of all of the semiconductor dies 500 are the same. In alterative embodiments, the sizes of some of the semiconductor dies 500 are different from each other, while the sizes of some of the semiconductor dies 500 are the same sizes. In further alternative embodiments, the sizes of all of the semiconductor dies 500 are different. In some embodiments, the shapes of all of the semiconductor dies 500 are identical. In alternative embodiments, the shapes of some of the semiconductor dies 500 are different from each other, while the shapes of some of the semiconductor dies 500 are identical. In further alternative embodiments, the shapes of all of the semiconductor dies 500 are different. The types, sizes and shapes of each of the semiconductor dies 500 are independent from each other, and may be selected and designed based on the demand and design layout, the disclosure is not limited thereto.

For example, as shown in FIG. 4, each of the semiconductor dies 600 includes a carrier die 610 having a surface S610t and a surface S610b opposing to the surface S610t, an interconnect structure 620 (including a dielectric structure 622 and patterned conductive layers 624) disposed over the surface S610t of the carrier die 610 and electrically coupled to the carrier die 610, a plurality of conductive vias 630 disposed over and electrically coupled to the interconnect 620, a plurality of stacking dies 650 disposed over the surface S610b of the carrier die 610 and electrically coupled to the carrier die 610, and an encapsulant 660, where the stacking dies 650 are sequentially stacked on (along the direction Z) and electrically coupled to the carrier die 610, the interconnect structure 620 is disposed between and electrically coupled to the conductive vias 630 and the carrier die 610, and the encapsulant 660 encapsulates the stacking dies 650 and covers the carrier die 610 exposed by the stacking dies 650. In some embodiments, the carrier die 610 is disposed between the encapsulant 660 and the interconnect structure 620 and between the stacking dies 650 and the interconnect structure 620, and the conductive vias 630 is protruded away from a surface of the interconnect structure 620.

It is noted that, each of the carrier die 610 and the stacking dies 650 may further include an interconnect structure (not shown). The carrier die 610 described herein may be referred as a semiconductor chip or an IC. In some embodiments, the carrier die 610 includes one or more digital chips, analog chips or mixed signal chips, such as an ASIC chip, a sensor chip, a wireless and RF chip, a logic chip or a voltage regulator chip. The logic chip may be a CPU, a GPU, a SoC, a microcontroller, or the like. In some embodiments, each of the stacking dies 650 includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash a wide I/O memory (WIO) die, a high bandwidth memory (HBM) die, the like, etc.). That is to say, the semiconductor dies 600 each includes a hybrid memory cube (HMC) module, a HBM module, or the like; in some embodiments. For example, the stacking dies 650 of each semiconductor die 600 may be HBM dies, and the carrier die 610 may be a logic die providing control functionality for these memory dies. The details, formation and material of the interconnect structure 620 (including the dielectric structure 622 and the patterned conductive layers 624) and the conductive vias 630 is similar to or substantially identical to the details, formation and material of the interconnect structure 120 (including the dielectric structure 122 and the patterned conductive layers 124) and the conductive vias 130, and thus are not repeated herein for brevity.

In some embodiments, the material of the encapsulant 660 includes a molding compound, a molding underfill, a resin (such as epoxy), or the like. In some alternative embodiments, the material of the encapsulant 660 includes nitride such as silicon nitride, oxide such as silicon oxide, phosphosilicate glass (PSG), borosilicate glass (BSG), boron-doped phosphosilicate glass (BPSG), a combination thereof, or the like. In yet alternative embodiments, the material of each of the encapsulant 660 includes an organic material (e.g., epoxy, PI, PBO, or the like), or the mixture of inorganic and organic materials (e.g., the mixture of silicon oxide and epoxy, or the like). In some embodiments, the encapsulant 660 may be formed by a molding process, such as a compression molding process. In some alternative embodiments, the encapsulant 660 may be formed through suitable fabrication techniques such as CVD (e.g., high-density plasma chemical vapor deposition (HDPCVD) or plasma-enhanced chemical vapor deposition (PECVD)). As illustrated in FIG. 4, for example, a back (or non-active) surface (not labeled) of the semiconductor die 600 includes a surface of the encapsulant 660 and a surface of outermost stacking die 650, where the surface of the encapsulant 660 and the surface of outermost stacking die 650 are substantially leveled with and substantially coplanar to each other. Alternatively or in addition to, an integrated passives (IPD) die, a voltage regulator (VR) die, a local silicon interconnect (LSI) die with or without deep trench capacitor (DTC) features, a local silicon interconnect die with multi-tier functions such as electrical and/or optical network circuit interfaces, IPD, VR, DTC, or the like may be included to substitute one or some of the semiconductor dies 600 or be further adopted. The type of the semiconductor dies 600 independently may be selected and/or designated depending on the demand and/or design layout, and thus is not specifically limited in the disclosure.

In some embodiments, the types of all of the semiconductor dies 600 are identical. In alternative embodiments, the types of some of the semiconductor dies 600 are different from each other, while the types of some of the semiconductor dies 600 are identical types. In further alternative embodiments, the types of all of the semiconductor dies 600 are different. In some embodiments, the sizes of some of the semiconductor dies 600 are different from each other, while the sizes of some of the semiconductor dies 600 are the same sizes. In alternative embodiments, the sizes of all of the semiconductor dies 600 are the same. In further alternative embodiments, the sizes of all of the semiconductor dies 600 are different. In some embodiments, the shapes of some of the semiconductor dies 600 are different from each other, while the shapes of some of the semiconductor dies 600 are identical. In alternative embodiments, the shapes of all of the semiconductor dies 600 are identical. In further alternative embodiments, the shapes of all of the semiconductor dies 600 are different. The types, sizes and shapes of each of the semiconductor dies 600 are independent from each other, and may be selected and designed based on the demand and design layout, the disclosure is not limited thereto.

For example, as shown in FIG. 4 through FIG. 5, the interposer 400 includes a plurality of bridge dies 410 (e.g., including bridge dies 410A, 410B, and/or 410C), a plurality of through vias 420, a redistribution circuit structure 430 (e.g., including a dielectric structure 432 and one or more metallization layers 434), a redistribution circuit structure 440 (e.g., including a dielectric structure 442 and one or more metallization layers 444), a plurality of conductive vias 450, an encapsulant 460, a plurality of connectors 470A (e.g., including conductive vias 472A and solder regions 474A) and a plurality of connectors 470B (e.g., including conductive vias 472B and solder regions 474B). In addition to or alternatively, the redistribution circuit structure 430 and/or the redistribution circuit structure 440 may be omitted. The interposer 400 may include a plurality of bridge dies 410 (e.g., including bridge dies 410A, 410B, and/or 410C), a plurality of through vias 420, a redistribution circuit structure 430 (e.g., including a dielectric structure 432 and one or more metallization layers 434), a plurality of conductive vias 450, an encapsulant 460, a plurality of connectors 470A (e.g., including conductive vias 472A and solder regions 474A) and a plurality of connectors 470B (e.g., including conductive vias 472B and solder regions 474B). Alternatively, the interposer 400 may include a plurality of bridge dies 410 (e.g., including bridge dies 410A, 410B, and/or 410C), a plurality of through vias 420, a redistribution circuit structure 440 (e.g., including a dielectric structure 442 and one or more metallization layers 444), a plurality of conductive vias 450, an encapsulant 460, a plurality of connectors 470A (e.g., including conductive vias 472A and solder regions 474A) and a plurality of connectors 470B (e.g., including conductive vias 472B and solder regions 474B). Or, the interposer 400 may include a plurality of bridge dies 410 (e.g., including bridge dies 410A, 410B, and/or 410C), a plurality of through vias 420, a plurality of conductive vias 450, an encapsulant 460, a plurality of connectors 470A (e.g., including conductive vias 472A and solder regions 474A) and a plurality of connectors 470B (e.g., including conductive vias 472B and solder regions 474B). In addition to or alternatively, the bonding pads 352 and the dielectric layer 362 may be omitted, the conductive vias 450 may be omitted. The interposer 400 may be referred to as an interconnect substrate, an interconnect structure, an interconnection substrate or an interconnection structure.

As shown in FIG. 4, the bridge dies 410A, 410B, 410C of the bridge dies 410 and the conductive pillars 420 are encapsulated in the encapsulant 460, the redistribution circuit structure 430 and the redistribution circuit structure 440 are disposed at two opposite sides of the encapsulant 460 and electrically coupled to the bridge dies 410A, 410B, 410C of the bridge dies 410 and the conductive pillars 420, for example. In some embodiments, the conductive vias 450 are disposed over and electrically coupled to the redistribution circuit structure 430, where the redistribution circuit structure 430 is disposed between the conductive vias 450 and the encapsulant 460. In some embodiments, the connectors 470A and 470B are disposed over and electrically coupled to the redistribution circuit structure 440, where the redistribution circuit structure 440 is disposed between the connectors 470A, 470B and the encapsulant 460. As shown in FIG. 4, some of the conductive vias 450 may be electrically coupled to the connectors 470A through the redistribution circuit structure 430, the conductive pillars 420, the bridge dies 410, and the redistribution circuit structure 440, and some of the conductive vias 450 may be electrically coupled to the connectors 470B through the redistribution circuit structure 430, the conductive pillars 420, the bridge dies 410, and the redistribution circuit structure 440.

The details, formation and material of each of the conductive pillars 420, the redistribution circuit structure 430, the redistribution circuit structure 440, the conductive vias 450, and the encapsulant 460 are respectively similar to or substantially identical to the details, formation and material of each of the through vias 320 (previously described in FIG. 1), the redistribution circuit structure 330 (previously described in FIG. 1), the redistribution circuit structure 340 (previously described in FIG. 1), the conductive vias 530, and the encapsulant 260, and thus are not repeated herein for brevity. In some embodiments, as shown in FIG. 4 and FIG. 5, the bridge dies 410A, 410B and 410C are substantially identical in the structure and functionality, except their lateral sizes (e.g., the dimensions in the X-Y plane). For example, in the plane view (e.g., the X-Y plane) or in the cross-sectional view of FIG. 4, a size of the bridge dies 410A is less than a size of the bridge dies 410B and a size of the bridge die(s) 410C, and the size of the bridge dies 410B is less than the size of the bridge die(s) 410C.

In a non-limiting embodiment of the bridge dies 410 as shown in FIG. 5, where one bridge die 410C is emphasized as exemplary example of a general structure of the bridge dies 410 (such as 410A, 410B and 410C), but the disclosure is not limited thereto. As shown in FIG. 5, the bridge die 410C may include a substrate 4110, a plurality of conductive pillars 4120 penetrating through the substrate 4110, an interconnect structure 4130 (including a dielectric structure 4132 and one or more metallization layers 4134) disposed over the substrate 4110 and electrically coupled to the conductive pillars 4120, an interconnect structure 4140 (including a dielectric structure 4142 and one or more metallization layers 4144) disposed over the substrate 4110 and electrically coupled to the conductive pillars 4120, a dielectric layer 4150 disposed over the interconnect structure 4130, a dielectric layer 4160 disposed over the interconnect structure 4140, a plurality of conductive vias 4170 disposed over and electrically coupled to the interconnect structure 4130 and laterally covered by the dielectric layer 4150, and a plurality of conductive vias 4180 disposed over and electrically coupled to the interconnect structure 4140 and laterally covered by the dielectric layer 4170, where the conductive vias 4170 penetrate through the dielectric layer 4150, and the conductive vias 4180 penetrate through the dielectric layer 4160. For example, an illustrated top surface of the dielectric layer 4150 is substantially level with illustrated top surfaces of the conductive vias 4170, and an illustrated top surface of the dielectric layer 4160 is substantially level with illustrated top surfaces of the conductive vias 4180. In other words, the illustrated top surface of the dielectric layer 4150 may be substantially coplanar to the illustrated top surfaces of the conductive vias 4170, and the illustrated top surface of the dielectric layer 4160 is substantially coplanar to the illustrated top surfaces of the conductive vias 4180. In alternative embodiments, the interconnect structure 4130 and/or the interconnect structure 4140 may be omitted. In addition to or alternative embodiments, the dielectric layer 4150 and/or the dielectric layer 4160 may be omitted. In addition to or alternative embodiments, the conductive vias 4170 and/or the conductive vias 4180 may be omitted.

In some embodiments, the substrate 4110 is a bulk semiconductor substrate, a silicon-on-insulator (SOI) substrate, a multi-layered semiconductor substrate, or the like. The semiconductor material of the substrate 4110 may be silicon, germanium; a compound semiconductor including silicon carbide, gallium arsenic, gallium phosphide, indium phosphide, indium arsenide, and/or indium antimonide; an alloy semiconductor including silicon germanium (SiGe), GaAsP, AlInAs, AlGaAs, GaInAs, GaInP, and/or GaInAsP; or combinations thereof. The alloy SiGe may be formed over a silicon substrate. The SiGe substrate may be strained. In an alternative embodiment, other substrates, such as multi-layered or gradient substrates, may also be used. The substrate 4110 may be doped or undoped. The substrate 4110 may include a wide variety of devices (not shown) (also referred to as semiconductor devices) formed therein. The devices may include active devices, passive devices, or a combination thereof. The devices may include integrated circuits devices. The devices may include transistors, capacitors, resistors, diodes, photodiodes, fuse devices, jumpers, inductors, or other similar devices. The functions of the devices may include memory, processors, sensors, amplifiers, power distribution, input/output circuitry, or the like. The devices each may be referred to as a semiconductor component. Alternatively, the substrate 4110 may be substantially free of active devices and passive devices, and merely provide routing functions. The formations and materials of the conductive vias 4120, the interconnect structure 4130, the interconnect structure 4140, the dielectric layer 4150 and the dielectric layer 4160 may be similar to or be substantially identical to the through vias 320, the redistribution circuit structure 330, the redistribution circuit structure 340, the dielectric layer 350 and the dielectric layer 360 previous described in FIG. 1, the formations and materials of the conductive vias 4170 and 4180 may be similar to or be substantially identical to the conductive vias 130 previous described in FIG. 1, and thus are not repeated herein for brevity. The through vias 4120 may be sometimes referred to as through-substrate-vias or through-silicon-vias as the substrate 4110 is a silicon substrate.

The connectors 470A and the connectors 470B may be disposed at the same side of the redistribution circuit structure 440 and electrically coupled to the redistribution circuit structure 440, as shown in FIG. 4. In some embodiments, a pitch P1 of the connectors 470A is greater than a pitch P2 of the connectors 470B. In some embodiments, a width W1 of the connectors 470A is greater than a width W2 of the connectors 470B. Alternatively, the width W1 of the connectors 470A may be substantially equal to the width W2 of the connectors 470B. Or, the width W1 of the connectors 470A may be less than the width W2 of the connectors 470B. In some embodiments, a height H1 of the connectors 470A is greater than a height H2 of the connectors 470B.

The formations and materials of the conductive vias 472A and 472B may be similar to or substantially identical to the formations and materials of the conductive vias 130 previously described in FIG. 1, and thus are not repeated herein. In some embodiments, the solder regions 474A and the solder regions 474B includes either eutectic solder or non-eutectic solder. The solder regions 474A and the solder regions 474B may include lead or be lead-free, and may include Sn—Ag, Sn—Cu, Sn—Ag—Cu, or the like.

In addition, each sub-package SD may further includes a plurality of semiconductor dies 1500 disposed on and electrically coupled to the interposer 400 and laterally next to the semiconductor dies 500, 600, as shown in FIG. 9. For example, the semiconductor dies 500 are arranged in an array, where the semiconductor dies 1500 and the semiconductor die 600 together surround the array of the semiconductor dies 500. The structure, formation and material of the semiconductor die 1500 may be similar to or substantially identical to the structure, formation and material of the semiconductor dies 500, and thus are not repeated herein. For example, the semiconductor dies 500 may be SoCs, the semiconductor dies 600 may be HBM modules, and the semiconductor dies 1500 may be input/output (I/O) interface dies. As shown in FIG. 9, in the plane view (e.g., the X-Y plane), a projection of the bridge die 100 may be overlapped with projections of the sub-packages SD. For example, in the plane view (e.g., the X-Y plane), the projection of the bridge die 100 is overlapped with at least a projection of at least one semiconductor die 500 of each of the sub-packages SD.

Continued on FIG. 4, in some embodiments, the semiconductor dies 500, 600 and 1500 (if any) are mounted to the interposer 400 (e.g., the conductive vias 450) through the connectors 50 by flip chip bonding. For example, the connectors 50 includes solder regions. The connectors 50 independently may include lead or be lead-free, and may include Sn—Ag, Sn—Cu, Sn—Ag—Cu, or the like. The connectors 50 independently may be referred to as solder regions, conductive connectors, conductive elements. For example, the connectors 50 include micro-bumps or the like.

In some embodiments, the optional underfill 710 fills the gaps between the interposer 400 and the semiconductor dies 500, between the interposer 400 and the semiconductor dies 600, between the interposer 400 and the semiconductor dies 1500 (if any) and between the semiconductor dies 500, 600, 1500 (if any). For example, the optional underfill 710 further extends onto sidewalls of semiconductor dies 500, 600, 1500 (if any). The optional underfill 710 may be any acceptable material, such as a polymer, epoxy resin, molding underfill, or the like, for example. The optional underfill 710 may be formed by underfill dispensing, a capillary flow process, or any other suitable method. Owing to the optional underfill 710, bonding strengths between the semiconductor dies 500 and the interposer 400, between the semiconductor dies 600 and the interposer 400 and between the semiconductor dies 1500 (if any) and the interposer 400 are enhanced. In some alternative embodiment, the optional underfill 710 may be omitted.

After mounting the semiconductor dies 500, 600 and 1500 (if any) to the interposer 400, the semiconductor dies 500, 600 and 1500 (if any) are encapsulated in the insulating encapsulation 810, where an illustrated top surface S810 of the insulating encapsulation 810 is substantially level with an illustrated top surface of the optional underfill 710, illustrated top surfaces (e.g., the surfaces S510b) of the semiconductor dies 500, illustrated top surfaces of the semiconductor dies 600 and illustrated top surfaces of the semiconductor dies 1500 (if any), in some embodiments. In other words, the illustrated top surface S810 of the insulating encapsulation 810 is substantially coplanar to the illustrated top surface of the optional underfill 710, the illustrated top surfaces (e.g., the surfaces S510b) of the semiconductor dies 500, the illustrated top surfaces of the semiconductor dies 600 and the illustrated top surfaces of the semiconductor dies 1500 (if any). That is, the semiconductor dies 500, 600 and 1500 (if any) and the optional underfill 710 are accessibly revealed by the insulating encapsulation 810. Alternatively, the semiconductor dies 500, 600 and 1500 (if any) and the optional underfill 710 are not exposed by the illustrated top surface S810 of the insulating encapsulation 810.

For example, the insulating encapsulation 810 laterally encapsulated the semiconductor dies 500, 600 and 1500 (if any) and the optional underfill 710 (e.g., a sidewall SW710 thereof) and covers the interposer 400 exposed therefrom. In some embodiments, the insulating encapsulation 810 is a molding compound formed by a molding process. In some embodiments, the insulating encapsulation 810 include polymers (such as epoxy resins, phenolic resins, silicon-containing resins, or other suitable resins), dielectric materials, or other suitable materials. In an alternative embodiment, the insulating encapsulation 810 may include an acceptable insulating encapsulation material. The insulating encapsulation 810 may further include inorganic filler or inorganic compound (e.g., silica, clay, and so on) which can be added therein to optimize coefficient of thermal expansion (CTE) of the insulating encapsulation 810, the disclosure is not limited thereto. The insulating encapsulation 810 may be referred to as an encapsulant, a dielectric encapsulation, or an encapsulation. For example, the insulating encapsulation 810 is formed by, but not limited to, over-molding the semiconductor dies 500, 600 and 1500 (if any) and the optional underfill 710 by an insulating encapsulation material, and patterning the insulating encapsulation material to form the insulating encapsulation 810. The insulating encapsulation material may be patterned by a planarizing process until obtaining a substantially flat and planar surface therefrom (e.g., S810). Owing to the insulating encapsulation 810, the semiconductor dies 500, 600 and 1500 (if any) and the optional underfill 710 are protected from the damages caused by the external contacts.

The planarizing process is performed by mechanical grinding, CMP, etching or combinations thereof, for example. The etching may include dry etching, wet etching, or a combination thereof. After the planarizing process, a cleaning process may be optionally performed to clean and remove the residue generated from the planarizing process. However, the disclosure is not limited thereto, and the planarizing process may be performed through any other suitable method. In the disclosure, the sub-packages SD are independently considered as a chip-on-wafer (CoW) package. For example, a sidewall SW810 of the insulating encapsulation 810 and a sidewall SW400 of the interposer 400 are substantially aligned to each other. This is to say, the sidewall SW810 of the insulating encapsulation 810 and the sidewall SW400 of the interposer 400 together constitute a sidewall of the sub-package SD, as shown in FIG. 4.

Referring to FIG. 6, in some embodiments, the sub-packages SD are mounted to the circuit substrate 300 through the connectors 470A by flip chip bonding and further mounted to the bridge die 100 through the connectors 470B by flip chip bonding. For example, the connectors 470A of the sub-packages SD are disposed on (e.g., in physical contact with) and electrically connected to the topmost layer of the metallization layers 334 of the redistribution circuit structure 330 of the circuit substrate 300. For example, the connectors 470B of the sub-packages SD are disposed on (e.g., in physical contact with) and electrically connected to the conductive vias 130 of the bridge die 100. Due to the bridge die 100, the sub-packages SD are electrically coupled to and electrically communicated to each other, where the bridge die 100 provides lateral electrical connections for the sub-packages SD. On the other hand, due to the circuit substrate 300, the sub-packages SD are electrically coupled to and electrically communicated to each other and to other later-formed component(s), where the circuit substrate 300 provides lateral electrical connections and vertical electrical connections for the sub-packages SD.

Referring to FIG. 7, in some embodiments, a plurality of semiconductor devices 900 are provided and mounted to the circuit substrate 300 through a plurality of connectors 52 by flip chip bonding. As shown in FIG. 7, the semiconductor devices 900 may be disposed on and electrically coupled to the circuit substrate 300 through directly connecting conductive vas 930 of the semiconductor devices 900 to the topmost layer of the metallization layers 334 of the redistribution circuit structure 330 of the circuit substrate 300 through the connectors 52. For example, the connectors 52 includes solder regions. The connectors 52 independently may include lead or be lead-free, and may include Sn—Ag, Sn—Cu, Sn—Ag—Cu, or the like. The connectors 52 independently may be referred to as solder regions, conductive connectors, conductive elements. For example, the connectors 52 include micro-bumps, controlled collapse chip connection (C4) bumps (for example, which may have, but not limited to, a size of about 80 μm) or the like. As shown in FIG. 9, the semiconductor devices 900 may be arranged along the edges of the sub-packages SD over the circuit substrate 300. The semiconductor devices 900 may include surface mount devices (SMDs) or an integrated passive devices (IPDs) that comprise passive devices such as resistors, inductors, capacitors, jumpers, combinations of these, or the like that are desired to be connected to and utilized in conjunction with the sub-packages SD.

Referring to FIG. 8, in some embodiments, an optional underfill 720 is formed to fill gaps between the sub-packages SD and the circuit substrate 300 and between the sub-packages SD and the bridge die 100. For example, the optional underfill 720 further extends onto sidewalls of the sub-packages SD, the sidewall S200 of the adhesive 200 and a sidewall of the bridge die 100. In some embodiments, the connectors 470A and the connectors 470B of the sub-packages SD are wrapped by (e.g., in physical contact with) the optional underfill 720. The optional underfill 720 may be any acceptable material, such as a polymer, epoxy resin, molding underfill, or the like, for example. The optional underfill 720 may be formed by underfill dispensing, a capillary flow process, or any other suitable method. Owing to the optional underfill 720, bonding strengths between the sub-packages SD and the circuit substrate 300 and between the sub-packages SD and the bridge die 100 are enhanced. In some alternative embodiment, the optional underfill 720 may be omitted.

In some embodiments, a plurality of connectors 4000 are formed over the circuit substrate 300, where the connectors 4000 are disposed on (e.g., in physical contact with) and electrically connected to the bottommost layer of the metallization layers 344 of the redistribution circuit structure 340 of the circuit substrate 300 exposed by the openings OP2. For example, the sub-packages SD are electrically coupled to some of the connectors 4000 through the connectors 470A (e.g., connecting to the topmost layer of metallization layers 334 of the redistribution circuit structure 330 of the circuit structure 300) and the circuit structure 300, and the semiconductor devices 900 are electrically coupled to some of the connectors 4000 through the connectors 52 (e.g., connecting to the topmost layer of metallization layers 334 of the redistribution circuit structure 330 of the circuit structure 300) and the circuit structure 300. The connectors 4000 includes a ball grid array (BGA) bumps (for example, which may have, but not limited to, a size of about 400 μm), electroless nickel-immersion gold technique (ENIG) formed bumps, electroless nickel-electroless palladium-immersion gold technique (ENEPIG) formed bumps, or the like, in some embodiments. The connectors 4000 may be referred to as conductive terminals, conductive connectors, conductive elements of the circuit structure 300 for external connections (e.g., to an motherboard or the like). Up to here, the semiconductor package SP1 is manufactured. In some embodiments, the semiconductor package SP1 has a chip-on-wafer-on-substrate structure.

In some embodiments, a thermal dissipating element is adopted, see a semiconductor package SP1′ of FIG. 10 and/or a semiconductor package SP1″ of FIG. 11. The elements similar to or substantially the same as the elements described above will use the same reference numbers, and certain details or descriptions of the same elements (e.g. the formations and materials) and the relationship thereof (e.g. the relative positioning configuration and electrical connection) will not be repeated herein.

Referring to FIG. 8 and FIG. 10 together, the semiconductor package SP1′ of FIG. 10 is similar to the semiconductor package SP1 of FIG. 8; the difference is that, the semiconductor package SP1′ of FIG. 10 further includes a thermal dissipating element 3000A, where the thermal dissipating element 3000A is adhered onto the circuit substrate 300 through an adhesive 1000. In some embodiments, as shown in FIG. 10, the thermal dissipating element 3000A is provided and then bonded to (e.g., attached to) the dielectric layer 350 of the circuit substrate 300 through the adhesive 1000, after the formation of the optional underfill 720 and prior to the formation of the connectors 4000 as previously described in the process of FIG. 8.

In some embodiments, as illustrated in FIG. 10, the thermal dissipating element 3000A includes a cover portion 3020 and a flange portion 3010 at the periphery of the cover portion 3020. In some embodiments, the cover portion 3020 is disposed over the sub-packages SD and the semiconductor devices 900, and extends substantially parallel to the circuit substrate 300. In some embodiments, the flange portion 3010 is disposed beside (aside of) the sub-packages SD and the semiconductor devices 900, located at an edge of the cover portion 3020, and projected towards the circuit substrate 300. For example, in a projection along the direction Z, the flange portion 3010 has an (continuously) annular shape disposed along the edge of the circuit substrate 300. In some embodiments, the flange portion 3010 extends in a direction perpendicular to the plane defined by the cover portion 3020. For example, the flange portion 3010 is in contact with the edge of the cover portion 3020. In some embodiments, the flange portion 3010 and the cover portion 3020 describe a right angle at their joint, but the disclosure is not limited thereto. Alternatively, the flange portion 3010 may be joined to the cover portion 3020 at different angles than 90 degrees. In some embodiments, as illustrated in FIG. 10, the sub-packages SD, the bridge die 100 and the semiconductor devices 900 are surrounded by (and distant from) the flange portion 3010, and the sub-packages SD are connected to the cover portion 3020 through a thermal interface material 2000. For example, the thermal dissipating element 3000A is thermally coupled to the sub-packages SD through the thermal interface material 2000.

The thermal interface material 2000 may include any suitable thermally conductive material such as a polymer having a good thermal conductivity, which may be between about 3 W/m·K to about 10 W/m·K or more. In some embodiments, the thermal interface material 2000 is a film type thermal interface material, such as graphene sheet, carbon nanotube sheet or the like, and is formed on the sub-packages SD by lamination or the like. The disclosure does not specifically limit a thickness of the thermal interface material 2000 as long as the thermal interface material 2000 is thick enough to sufficiently dissipating heat from the sub-packages SD to the later-formed heat dissipating element. The thermal dissipating element 3000A, for example, has a high thermal conductivity between about 200 W/m·K to about 400 W/m·K or more, and is formed using a metal, a metal alloy, and the like. In some embodiments, the flange portion 3010 and the cover portion 3020 of the thermal dissipating element 3000A are an integral piece.

In some embodiments, the adhesive 1000 is formed in a manner of a continuous pad having an (continuously) annular shape located on the circuit substrate 300, where the adhesive 1000 is disposed on the circuit substrate 300 where only the thermal dissipating element 3000A is expected to contact the circuit substrate 300. For example, the closed frame shape of the adhesive 1000 corresponds to the shape of the flange portion 3010 of the thermal dissipating element 3000A. The closed frame shape of the adhesive 1000 may be in a circular, a rectangular, ellipse, or polygonal form.

A material of the adhesive 1000 is not particularly limited, and may be chosen as a function of a material used for adhering the circuit substrate 300 and the thermal dissipating element 3000A (e.g. the flange portion 3020), where the adhesive 1000 has to secure the circuit substrate 300 and the thermal dissipating element 3000A together. For example, a material of the adhesive 1000 includes a thermo-curable adhesive, photocurable adhesive, thermally conductive adhesive, thermosetting resin, waterproof adhesive, lamination adhesive or a combination thereof. In some embodiments, the material of the adhesive 1000 includes a thermally conductive adhesive. For another example, the adhesive 1000 includes a die attach film (DAF). According to the type of material used, the adhesive 1000 may be formed by deposition, lamination, printing, plating, or any other suitable technique. In certain embodiments, depending on the material of the adhesive 1000, the circuit substrate 300 may be thermally coupled to thermal dissipating element 3000A through the adhesive 1000. In some embodiments, the adhesive 1000 includes a thermal adhesive, and thus the thermal dissipating element 3000A further thermally coupled to the circuit substrate 300. For example, as shown in FIG. 10, the sub-packages SD are arranged within an inner cavity confined by the thermal dissipating element 3000A and the circuit substrate 300. Up to here, the package structure PS′ is manufactured. In some embodiments, for the package structure PS1′, the thermal dissipating element 3000A provides physical protection to the sub-packages SD in addition to the functionality of dissipating heat. In some embodiments, the thermal dissipating element 3000A is referred to as a thermal dissipating lid.

Referring to FIG. 8 and FIG. 11 together, the semiconductor package SP1″ of FIG. 11 is similar to the semiconductor package SP1 of FIG. 8; the difference is that, the semiconductor package SP1″ of FIG. 11 further includes a thermal dissipating element 3000B adhered onto the circuit substrate 300 through an adhesive 1000. In some embodiments, as shown in FIG. 11, the thermal dissipating element 3000B is provided and then bonded to (e.g., attached to) the dielectric layer 350 of the circuit substrate 300 through the adhesive 1000, after the formation of the optional underfill 720 and prior to the formation of the connectors 4000 previously described in FIG. 8.

In some embodiments, as illustrated in FIG. 11, the thermal dissipating element 3000B includes a flange portion 3010, solely. In some embodiments, the flange portion 3010 is disposed beside (aside of) and surrounds the sub-packages SD and the semiconductor devices 900, and projected towards the circuit substrate 300. In other words, the flange portion 3010 extends in a direction normal to the circuit substrate 300. In some embodiments, as illustrated in FIG. 11, the sub-packages SD, the bridge die 100 and the semiconductor devices 900 are surrounded by (and distant from) the flange portion 3010. According to the type of material used, the adhesive 1000 may be formed by deposition, lamination, printing, plating, or any other suitable technique. In certain embodiments, depending on the material of the adhesive 1000, the circuit substrate 300 may be thermally coupled to thermal dissipating element 3000B through the adhesive 1000. In some embodiments, the adhesive 1000 includes a thermal adhesive, and thus the thermal dissipating element 3000B further thermally coupled to the circuit substrate 300. In some embodiments, for the package structure PS1″, the thermal dissipating element 3000B provides physical protection to the sub-packages SD in addition to the functionality of dissipating heat. In some embodiments, the thermal dissipating element 3000B is referred to as a thermal dissipating ring. The details, formations and materials of the flange portion 3010 and the adhesive 1000 have been discussed in FIG. 10, and thus are not repeated herein for brevity. As shown in FIG. 11, a height of the flange portion 3010 is larger than a height of the sub-packages SD, for example.

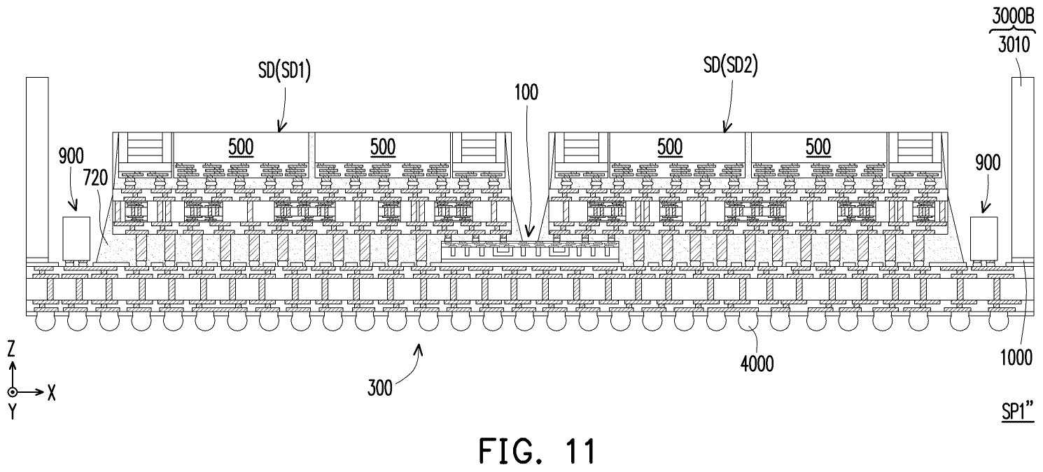

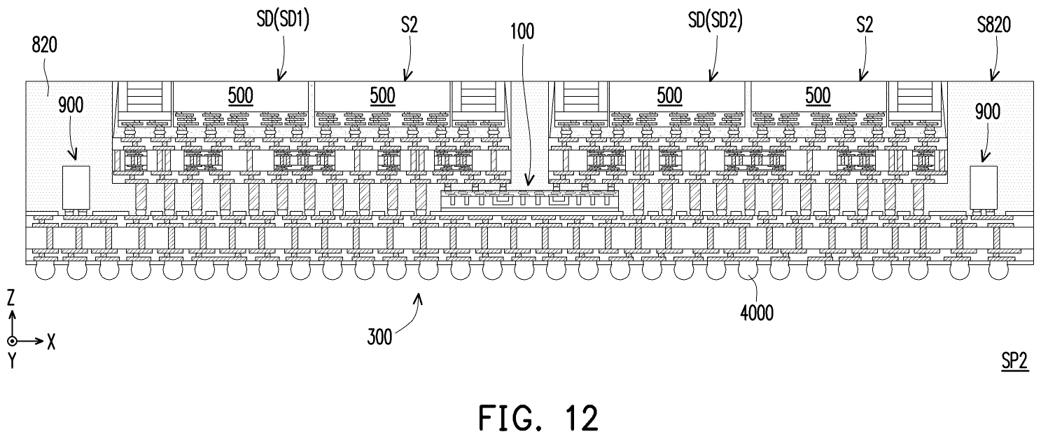

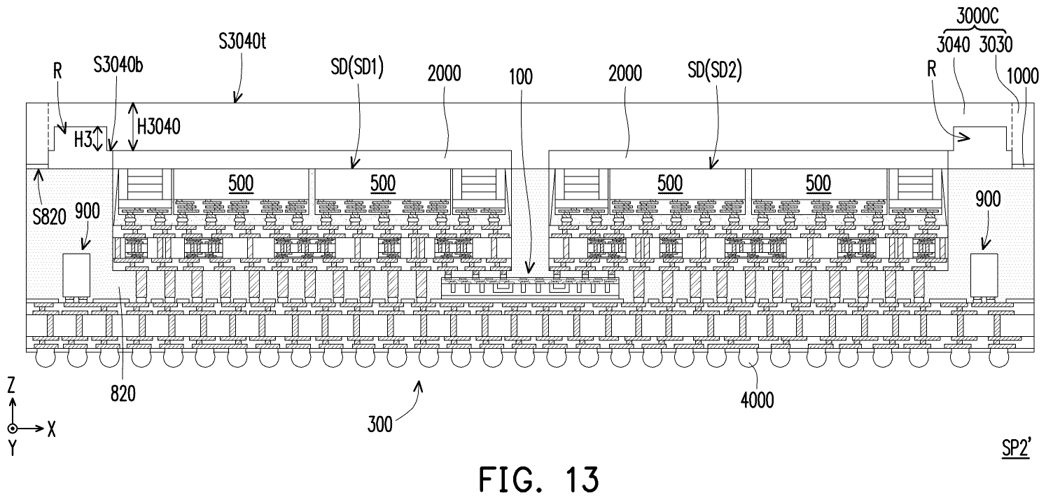

FIG. 12 is a schematic cross-sectional view of a semiconductor package (e.g., SP2) in accordance with some embodiments of the disclosure. FIG. 13 through FIG. 14 are respectively a schematic cross-sectional view of a semiconductor package (e.g., SP2′ or SP″) in accordance with some alternative embodiments of the disclosure. The elements similar to or substantially the same as the elements described above will use the same reference numbers, and certain details or descriptions of the same elements (e.g. the formations and materials) and the relationship thereof (e.g. the relative positioning configuration and electrical connection) will not be repeated herein.

Referring to FIG. 12, in some embodiments, an insulating encapsulation 820 is formed over the circuit structure 300 to encapsulate the semiconductor devices 900, the sub-packages SD and the bridge die 100 so to form the semiconductor package SP2, following the process as described in FIG. 7. For example, the insulating encapsulation 820 laterally encapsulates the sub-packages SD and embedded the bridge die 100 and the semiconductor devices 900, where the circuit substrate 300 exposed by the semiconductor devices 900, the bridge die 100 and the sub-packages SD are covered by (e.g., in physical contact with) the insulating encapsulation 820. In some embodiments, an illustrated top surface S820 of the insulating encapsulation 820 is accessibly revealed the sub-packages SD. For example, the illustrated top surface S820 of the insulating encapsulation 820 is substantially level with a surface S2 (e.g., the rear side/surface or the non-active side/surface) of the sub-packages SD. In other words, the illustrated top surface S820 of the insulating encapsulation 820 is substantially coplanar to the surface S2 (e.g., the rear side/surface or the non-active side/surface) of the sub-packages SD. In some embodiments, a sidewall (no labeled) of the insulating encapsulation 820 and a sidewall (no labeled) of the circuit substrate 300 are substantially aligned to each other. As shown in FIG. 12, a sidewall (no labeled) of the insulating encapsulation 820 and a sidewall (no labeled) of the circuit substrate 300 may together constitute a sidewall of the semiconductor package SP2. The formation and material of the insulating encapsulation 820 may be similar to or substantially identical to the formation and material of the insulating encapsulation 810 previously described in FIG. 4, and thus are not repeated herein for brevity.

In some embodiments, a thermal dissipating element is adopted, see a semiconductor package SP2′ of FIG. 13 and/or a semiconductor package SP2″ of FIG. 14. The elements similar to or substantially the same as the elements described above will use the same reference numbers, and certain details or descriptions of the same elements (e.g. the formations and materials) and the relationship thereof (e.g. the relative positioning configuration and electrical connection) will not be repeated herein.

Referring to FIG. 12 and FIG. 13 together, the semiconductor package SP2′ of FIG. 13 is similar to the semiconductor package SP2 of FIG. 12; the difference is that, the semiconductor package SP2′ of FIG. 13 further includes a thermal dissipating element 3000C, where the thermal dissipating element 3000C is adhered onto the insulating encapsulation 820 through an adhesive 1000. In some embodiments, as shown in FIG. 13, the thermal dissipating element 3000C is provided and then bonded to (e.g., attached to) a surface S820 of the insulating encapsulation 820 through the adhesive 1000, prior to the formation of the connectors 4000 as previously described in the process of FIG. 8 (without forming the optional underfill 720).

In some embodiments, as illustrated in FIG. 13, the thermal dissipating element 3000C includes a cover portion 3040 and a flange portion 3030 at the periphery of the cover portion 3040, wherein a recess R is formed in the cover portion 3040 proximately to the flange portion 3030. In some embodiments, the recess R has an opening hole at a surface S3040b and extends into the cover portion 3040 from the surface S3040b toward to the surface S3040t in the direction Z, where the recess R stops at a position inside the cover portion 3040. The surface S3040t may be opposite to the surface S3040b in the direction Z. For example, a thickness H3 of the recess R is less than a thickness H3040 of the cover portion 3040. For example, in a projection along the direction Z, the recess R has an (continuously) annular shape disposed along the inner edge of the flange portion 3030 and distant from the sub-packages SD. As shown in FIG. 13, the recess R may not be not revealed by the surface S3040t of the cover portion 3040. The sub-packages SD are thermally coupled to the cover portion 3040 of the thermal dissipating element 3000C through a thermal interface material 2000, as shown in FIG. 13, in some embodiments. The formations and materials of the thermal dissipating element 3000C (including the cover portion 3040 and the flange portion 3030) are similar to or substantially identical to the formations and materials of the dissipating element 3000A (including the cover portion 3020 and the flange portion 3010) previously described in FIG. 10, the details, formations and materials of the thermal interface material 2000 and the adhesive 1000 have been discussed in FIG. 10, and thus are not repeated herein for brevity. In some embodiments, for the package structure PS2′, the thermal dissipating element 3000C provides physical protection to the sub-packages SD in addition to the functionality of dissipating heat. In some embodiments, the thermal dissipating element 3000C is referred to as a thermal dissipating lid.

Referring to FIG. 12 and FIG. 14 together, the semiconductor package SP2″ of FIG. 14 is similar to the semiconductor package SP2 of FIG. 12; the difference is that, the semiconductor package SP2″ of FIG. 14 further includes a thermal dissipating element 3000D adhered onto an insulating encapsulation 820 through an adhesive 1000. In some embodiments, as shown in FIG. 11, the thermal dissipating element 3000D is provided and then bonded to (e.g., attached to) a surface S820 of the insulating encapsulation 820, prior to the formation of the connectors 4000 previously described in FIG. 8 (without forming the optional underfill 720).

In some embodiments, as illustrated in FIG. 14, the thermal dissipating element 3000D includes a flange portion 3030, solely. In some embodiments, in the projection along the direction Z, the flange portion 3030 is disposed beside (aside of) and surrounds the sub-packages SD and the semiconductor devices 900, and projected towards the insulating encapsulation 820. In other words, the flange portion 3030 extends in a direction normal to the insulating encapsulation 820. In some embodiments, as illustrated in FIG. 14, the sub-packages SD, the bridge die 100 and the semiconductor devices 900 are surrounded by (and distant from) the flange portion 3010. According to the type of material used, the adhesive 1000 may be formed by deposition, lamination, printing, plating, or any other suitable technique. In certain embodiments, depending on the material of the adhesive 1000, the insulating encapsulation 820 may be thermally coupled to thermal dissipating element 3000D through the adhesive 1000. In some embodiments, the adhesive 1000 includes a thermal adhesive, and thus the thermal dissipating element 3000D further thermally coupled to the insulating encapsulation 820. In some embodiments, for the package structure PS2″, the thermal dissipating element 3000D provides physical protection to the sub-packages SD in addition to the functionality of dissipating heat. In some embodiments, the thermal dissipating element 3000D is referred to as a thermal dissipating ring. The details, formations and materials of the flange portion 3030 and the adhesive 1000 have been discussed in FIG. 10, and thus are not repeated herein for brevity.

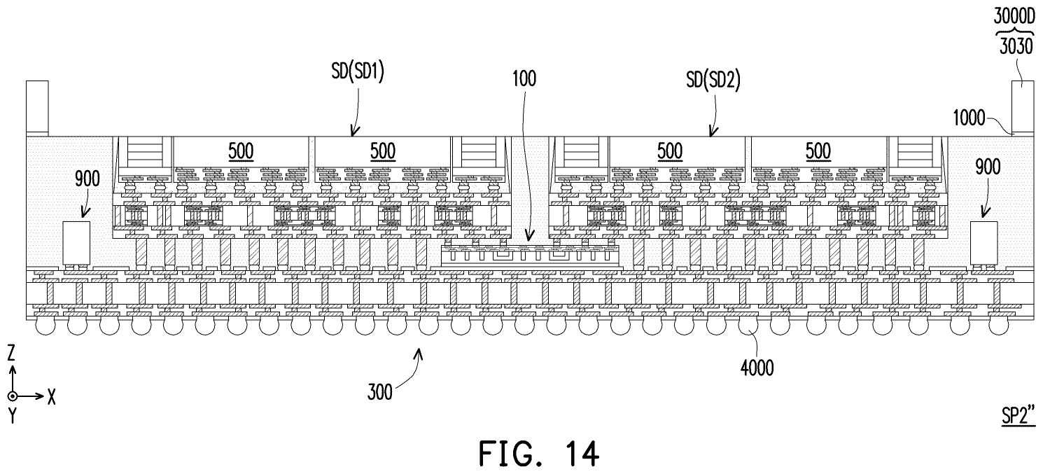

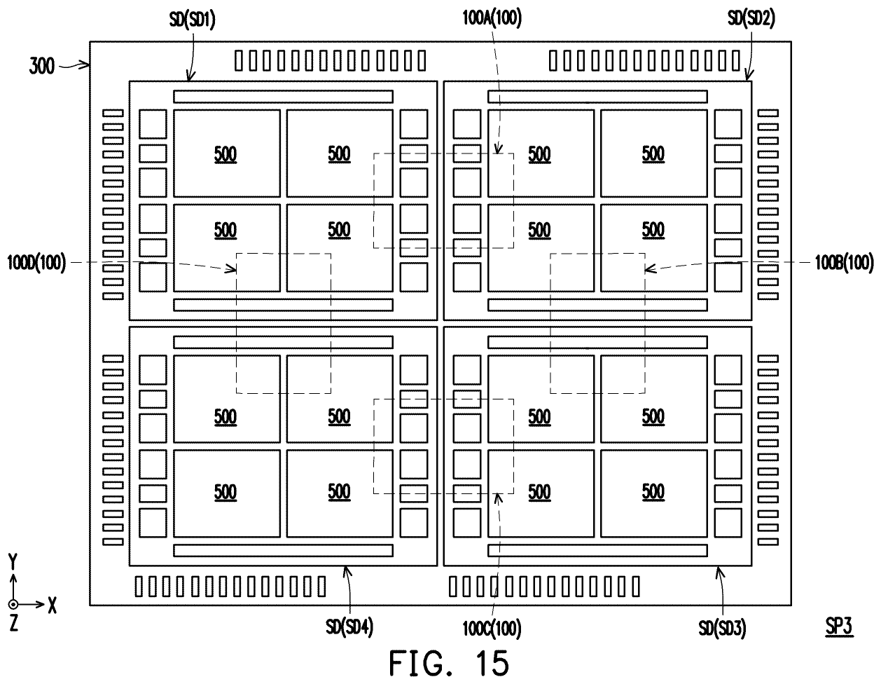

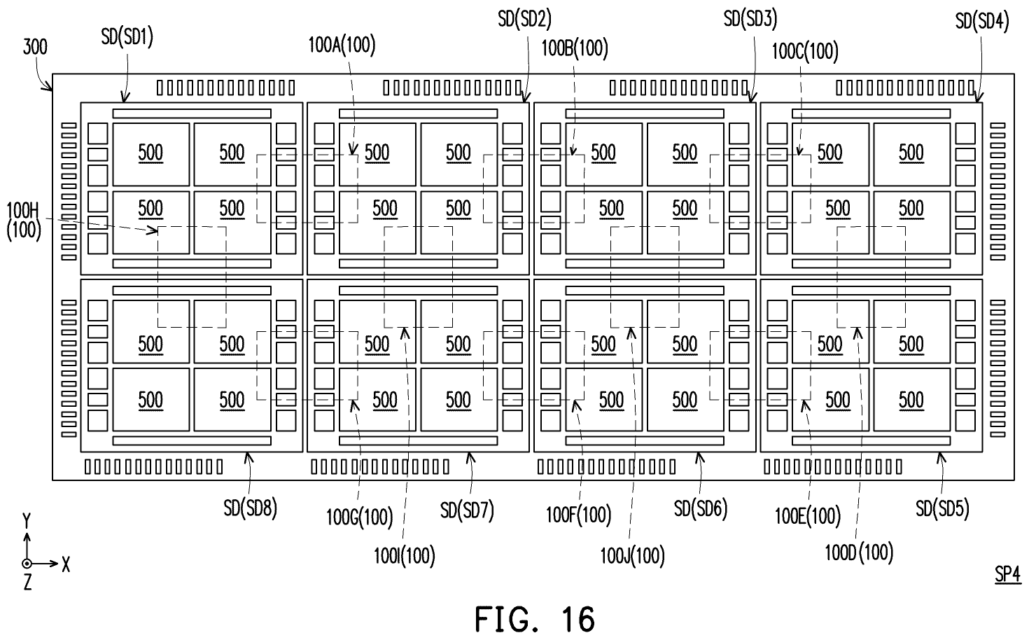

In the above embodiments of which the semiconductor package including two sub-packages SD (e.g., SD1 and SD2) electrically coupled to and electrically communicated with each other by a bridge die (e.g., 100). However, the disclosure is not limited to the number of sub-packages SD in each semiconductor package depicted in FIG. 9, the number of the number of sub-packages SD in each semiconductor package may be more than two (see FIG. 15 and FIG. 16). In the disclosure, the number of the number of sub-packages SD in each semiconductor package may be selected and designated based on demand and the design layout. FIG. 15 through FIG. 16 are respectively a schematic plane view of a semiconductor package in accordance with some alternative embodiments of the disclosure. The elements similar to or substantially the same as the elements described above will use the same reference numbers, and certain details or descriptions of the same elements (e.g. the formations and materials) and the relationship thereof (e.g. the relative positioning configuration and electrical connection) will not be repeated herein.

Referring to FIG. 15, in some embodiment, a semiconductor package SP3 includes a plurality of sub-packages SD including a sub-package SD1, a sub-package SD2, a sub-package SD3 and a sub-package SD4 each disposed on and electrically coupled to a circuit substrate 300, a plurality of semiconductor devices 900 disposed on and electrically coupled to the circuit substrate 300 and arranged to surround the sub-packages SD, and a plurality of bridge dies 100 including a bridge die 100A, a bridge die 100B, a bridge die 100C and a bridge die 100D each disposed on and electrically coupled to the circuit substrate 300, and a plurality of connectors 4000 disposed on and electrically coupled to the circuit substrate 300 and being opposite to the sub-packages SD, the semiconductor devices 900 and the bridge dies 100. For example, the sub-package SD1 is electrically coupled to and electrically communicated with the sub-package SD2 through the bridge die 100A, the sub-package SD2 is electrically coupled to and electrically communicated with the sub-package SD3 through the bridge die 100B, the sub-package SD3 is electrically coupled to and electrically communicated with the sub-package SD4 through the bridge die 100C, and the sub-package SD4 is electrically coupled to and electrically communicated with the sub-package SD1 through the bridge die 100D. In some embodiments, the bridge dies 100 are adhered onto the circuit substrate 300 through an adhesive 2000, where there is no direct metal-to-metal contact between the bridge dies 100 and the circuit substrate 300. In a non-limiting example, the semiconductor package PS3 further includes an optical underfill 720 between the sub-packages SD, the bridge dies 100 and the circuit substrate 300, similar to FIG. 8. In another non-limiting example, the semiconductor package PS3 further includes an optical underfill 720 between the sub-packages SD, the bridge dies 100 and the circuit substrate 300, a thermal dissipating element 3000A adhered onto the circuit substrate 300 through the adhesive 1000 and a thermal interface material 2000 between the sub-packages SD and the thermal dissipating element 3000A, similar to FIG. 10. In another non-limiting example, the semiconductor package PS3 further includes an optical underfill 720 between the sub-packages SD, the bridge dies 100 and the circuit substrate 300 and a thermal dissipating element 3000B adhered onto the circuit substrate 300 through the adhesive 1000, similar to FIG. 11.

Or, in a non-limiting example, the semiconductor package PS3 further includes an insulating encapsulation 820 between the sub-packages SD, the bridge dies 100, the semiconductor dies 900 and the circuit substrate 300, similar to FIG. 12. In another non-limiting example, the semiconductor package PS3 further includes an insulating encapsulation 820 between the sub-packages SD, the bridge dies 100, the semiconductor dies 900 and the circuit substrate 300, a thermal dissipating element 3000C adhered onto the insulating encapsulation 820 through the adhesive 1000 and a thermal interface material 2000 between the sub-packages SD and the thermal dissipating element 3000C, similar to FIG. 13. In another non-limiting example, the semiconductor package PS3 further includes an insulating encapsulation 820 between the sub-packages SD, the bridge dies 100, the semiconductor dies 900 and the circuit substrate 300 and a thermal dissipating element 3000D adhered onto the insulating encapsulation 820 through the adhesive 1000, similar to FIG. 14.

Referring to FIG. 16, in some embodiment, a semiconductor package SP4 includes a plurality of sub-packages SD including a sub-package SD1, a sub-package SD2, a sub-package SD3, a sub-package SD4, a sub-package SD5, a sub-package SD6, a sub-package SD7 and a sub-package SD8 each disposed on and electrically coupled to a circuit substrate 300, a plurality of semiconductor devices 900 disposed on and electrically coupled to the circuit substrate 300 and arranged to surround the sub-packages SD, and a plurality of bridge dies 100 including a bridge die 100A, a bridge die 100B, a bridge die 100C, a bridge die 100D, a bridge die 100E, a bridge die 100F, a bridge die 100G, a bridge die 100H, a bridge die 100I and a bridge die 100J each disposed on and electrically coupled to the circuit substrate 300, and a plurality of connectors 4000 disposed on and electrically coupled to the circuit substrate 300 and being opposite to the sub-packages SD, the semiconductor devices 900 and the bridge dies 100. For example, the sub-package SD1 is electrically coupled to and electrically communicated with the sub-package SD2 through the bridge die 100A, the sub-package SD2 is electrically coupled to and electrically communicated with the sub-package SD3 through the bridge die 100B, the sub-package SD3 is electrically coupled to and electrically communicated with the sub-package SD4 through the bridge die 100C, the sub-package SD4 is electrically coupled to and electrically communicated with the sub-package SD5 through the bridge die 100D, the sub-package SD5 is electrically coupled to and electrically communicated with the sub-package SD6 through the bridge die 100E, the sub-package SD6 is electrically coupled to and electrically communicated with the sub-package SD7 through the bridge die 100F, the sub-package SD7 is electrically coupled to and electrically communicated with the sub-package SD8 through the bridge die 100G, the sub-package SD8 is electrically coupled to and electrically communicated with the sub-package SD1 through the bridge die 100H, the sub-package SD2 is electrically coupled to and electrically communicated with the sub-package SD7 through the bridge die 100I, and the sub-package SD3 is electrically coupled to and electrically communicated with the sub-package SD6 through the bridge die 100J. In some embodiments, the bridge dies 100 are adhered onto the circuit substrate 300 through an adhesive 2000, where there is no direct metal-to-metal contact between the bridge dies 100 and the circuit substrate 300. In a non-limiting example, the semiconductor package PS4 further includes an optical underfill 720 between the sub-packages SD, the bridge dies 100 and the circuit substrate 300, similar to FIG. 8. In another non-limiting example, the semiconductor package PS4 further includes an optical underfill 720 between the sub-packages SD, the bridge dies 100 and the circuit substrate 300, a thermal dissipating element 3000A adhered onto the circuit substrate 300 through the adhesive 1000 and a thermal interface material 200 between the sub-packages SD and the thermal dissipating element 3000A, similar to FIG. 10. In another non-limiting example, the semiconductor package PS4 further includes an optical underfill 720 between the sub-packages SD, the bridge dies 100 and the circuit substrate 300 and a thermal dissipating element 3000B adhered onto the circuit substrate 300 through the adhesive 1000, similar to FIG. 11.

Or, in a non-limiting example, the semiconductor package PS4 further includes an insulating encapsulation 820 between the sub-packages SD, the bridge dies 100, the semiconductor dies 900 and the circuit substrate 300, similar to FIG. 12. In another non-limiting example, the semiconductor package PS4 further includes an insulating encapsulation 820 between the sub-packages SD, the bridge dies 100, the semiconductor dies 900 and the circuit substrate 300, a thermal dissipating element 3000C adhered onto the insulating encapsulation 820 through the adhesive 1000 and a thermal interface material 2000 between the sub-packages SD and the thermal dissipating element 3000C, similar to FIG. 13. In another non-limiting example, the semiconductor package PS4 further includes an insulating encapsulation 820 between the sub-packages SD, the bridge dies 100, the semiconductor dies 900 and the circuit substrate 300 and a thermal dissipating element 3000D adhered onto the insulating encapsulation 820 through the adhesive 1000, similar to FIG. 14.

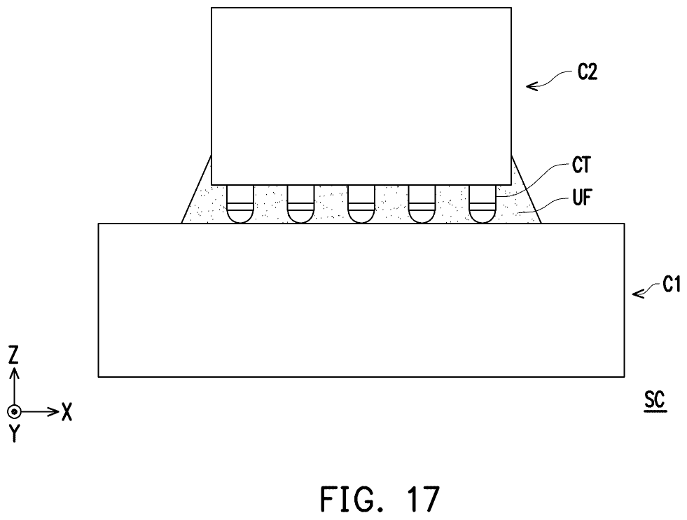

The semiconductor packages SP1, SP1′, SP1″, SP2, SP2′, SP2″, SP3, SP4 or the modifications thereof may be further mounted onto another external/additional electronical component, for example, mounted onto a circuit structure, such as a motherboard, a package substrate, another printed circuit board (PCB), a printed wiring board, and/or other carrier that is capable of carrying integrated circuits. FIG. 17 is a schematic cross-sectional view of an application of a semiconductor package in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 17, in some embodiments, a component assembly SC including a first component C1 and a second component C2 disposed over the first component C1 is provided. The first component C1 may be or may include a circuit structure, such as a motherboard, a package substrate, another PCB, a printed wiring board, an interposer, and/or other carrier that is capable of carrying integrated circuits. In some embodiments, the second component C2 mounted on the first component C1 is similar to one of the semiconductor packages SP1, SP1′, SP1″, SP2, SP2′, SP2″, SP3, SP4 or the modifications thereof. In a non-limiting example, one or more semiconductor packages (e.g., one or multiple semiconductor packages SP1, SP1′, SP1″, SP2, SP2′, SP2″, SP3, SP4 or the modifications thereof) may be electrically coupled to the first component C1 through a plurality of terminals CT. The terminals CT may be the connectors 4000 as previously described.

In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill may be formed by underfill dispensing, a capillary flow process, or any other suitable method. Owing to the underfill UF, a bonding strength between the first component C1 and the second component C2 is enhanced.

In accordance with some embodiments, a semiconductor package includes a substrate, a bridge die, a first sub-package and a second sub-package, and a plurality of connectors. The bridge die is adhered on a first side of the substrate by an adhesive. The first sub-package and the second sub-package are disposed on the substrate and electrically coupled to the substrate and the bridge die, where the bridge die is disposed between the first sub-package and the substrate. The plurality of connectors are disposed on a second side of the substrate, the first side is opposite to the second side, where the plurality of connectors is electrically coupled to the substrate.

In accordance with some embodiments, a semiconductor package includes a circuit substrate, a bridge die, a first sub-package, and a second sub-package. The bridge die is fixed on a dielectric layer of the circuit substrate. The first sub-package includes a first group of first connectors and a first group of second connectors, where the first sub-package is disposed on and electrically coupled to the circuit substrate through the first group of first connectors and is disposed on and electrically coupled to the bridge die through the first group of second connectors, and a height of the first group of first connectors is greater than a height of the first group of second connectors. The second sub-package includes a second group of first connectors and a second group of second connectors, where the second sub-package is disposed on and electrically coupled to the circuit substrate through the second group of first connectors and is disposed on and electrically coupled to the bridge die through the second group of second connectors, and a height of the second group of first connectors is greater than a height of the second group of second connectors.

In accordance with some embodiments, a method of manufacturing a semiconductor package includes the following steps: providing a substrate; adhering a bridge die over the substrate through an adhesive; mounting a first sub-package and a second sub-package to the substrate and the bridge die, the first sub-package and the second sub-package being electrically coupled to the substrate and the bridge die, wherein the bridge die is disposed between the first sub-package and the substrate and between the second sub-package and the substrate; and disposing a plurality of connectors over the substrate, the substrate being disposed between the plurality of connectors and the bridge die, wherein the plurality of connectors is electrically coupled to the substrate.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor package, comprising:
a substrate;
a bridge die, adhered on a first side of the substrate by an adhesive;
a first sub-package and a second sub-package, disposed on the substrate and electrically coupled to the substrate and the bridge die, wherein the bridge die is disposed between the first sub-package and the substrate; and
a plurality of connectors, disposed on a second side of the substrate, the first side being opposite to the second side, wherein the plurality of connectors is electrically coupled to the substrate.

2. The semiconductor package of claim 1,
wherein the first sub-package comprises:
a first interposer;
a first plurality of first semiconductor dies, disposed on and electrically coupled to the first interposer; and
a first plurality of second semiconductor dies, disposed on and electrically coupled to the interposer, wherein the first plurality of second semiconductor dies are laterally arranged next to the first plurality of first semiconductor dies over the first interposer and electrically coupled to the first plurality of first semiconductor dies through the first interposer, and
wherein the second sub-package comprises:
a second interposer;
a second plurality of first semiconductor dies, disposed on and electrically coupled to the second interposer; and
a second plurality of second semiconductor dies, disposed on and electrically coupled to the second interposer, wherein the second plurality of second semiconductor dies are laterally arranged next to the second plurality of first semiconductor dies over the second interposer and electrically coupled to the second plurality of first semiconductor dies through the second interposer.

3. The semiconductor package of claim 1, further comprising:
a plurality of semiconductor devices, disposed on and electrically coupled to the substrate, wherein the plurality of semiconductor devices are arranged along an edge of at least one of the first sub-package or the second sub-package.

4. The semiconductor package of claim 1, wherein in a stacking direction of the plurality of connectors and the substrate, a projection of the first sub-package and a projection of the second sub-package are overlapped with a projection of the bridge die.

5. The semiconductor package of claim 1, further comprising:
a thermal dissipating element, disposed on the substrate, and comprising:
a cover portion, extending over the first sub-package and the second sub-package and thermally coupled to the first sub-package and the second sub-package through a thermal interface material disposed therebetween; and
a flange portion, disposed at and surrounds an edge of the cover portion, wherein the flange portion is extended toward to the substrate and thermally coupled to the substrate through an additional adhesive disposed therebetween.

6. The semiconductor package of claim 5, wherein the cover portion and the flange portion of the thermal dissipating element are an integral piece.

7. The semiconductor package of claim 1, further comprising:
a thermal dissipating ring, disposed on and thermally coupled to the substrate through an additional adhesive disposed therebetween, wherein the thermal dissipating ring surrounds the first sub-package and the second sub-package.

8. A semiconductor package, comprising:
a circuit substrate;
a bridge die, fixed on a dielectric layer of the circuit substrate;
a first sub-package comprising a first group of first connectors and a first group of second connectors, wherein the first sub-package is disposed on and electrically coupled to the circuit substrate through the first group of first connectors and is disposed on and electrically coupled to the bridge die through the first group of second connectors, and a height of the first group of first connectors is greater than a height of the first group of second connectors; and
a second sub-package comprising a second group of first connectors and a second group of second connectors, wherein the second sub-package is disposed on and electrically coupled to the circuit substrate through the second group of first connectors and is disposed on and electrically coupled to the bridge die through the second group of second connectors, and a height of the second group of first connectors is greater than a height of the second group of second connectors.

9. The semiconductor package of claim 8, wherein the bridge die is fixed on the dielectric layer of the circuit substrate through a die attach film.

10. The semiconductor package of claim 9, wherein a sidewall of the bridge die is aligned with a sidewall of the die attached film in a cross-section of the semiconductor package along a stacking direction of the circuit substrate and the bridge die.

11. The semiconductor package of claim 9, wherein a sidewall of the bridge die is extended beyond a sidewall of the die attached film in a cross-section of the semiconductor package along a stacking direction of the circuit substrate and the bridge die.

12. The semiconductor package of claim 9, wherein a sidewall of the die attached film is extended beyond a sidewall of the bridge die in a cross-section of the semiconductor package along a stacking direction of the circuit substrate and the bridge die.

13. The semiconductor package of claim 8, further comprising:
a plurality of connectors, disposed on and electrically coupled to the circuit substrate, the circuit substrate being between the bridge die and the plurality of connectors; and
a thermal dissipating element, disposed on the circuit substrate, and comprising:
a cover portion, extending over the first sub-package and the second sub-package and thermally coupled to the first sub-package and the second sub-package through a thermal interface material disposed therebetween; and
a flange portion, disposed at and surrounds an edge of the cover portion, wherein the flange portion is extended toward to the circuit substrate and thermally coupled to the circuit substrate through an additional adhesive disposed therebetween.

14. The semiconductor package of claim 8, further comprising:
a plurality of connectors, disposed on and electrically coupled to the circuit substrate, the circuit substrate being between the bridge die and the plurality of connectors; and
a thermal dissipating ring, disposed on and thermally coupled to the circuit substrate through an additional adhesive disposed therebetween, wherein the thermal dissipating ring surrounds the first sub-package and the second sub-package.

15. The semiconductor package of claim 8, wherein a width of the first group of first connectors is greater than a width of the first group of second connectors, and a width of the second group of first connectors is greater than a width of the second group of second connectors.

16. The semiconductor package of claim 8, wherein a pitch of the first group of first connectors is greater than a pitch of the first group of second connectors, and a pitch of the second group of first connectors is greater than a pitch of the second group of second connectors.

17. A method of manufacturing a semiconductor package, comprising:
providing a substrate;
adhering a bridge die over the substrate through an adhesive;
mounting a first sub-package and a second sub-package to the substrate and the bridge die, the first sub-package and the second sub-package being electrically coupled to the substrate and the bridge die, wherein the bridge die is disposed between the first sub-package and the substrate and between the second sub-package and the substrate; and
disposing a plurality of connectors over the substrate, the substrate being disposed between the plurality of connectors and the bridge die, wherein the plurality of connectors is electrically coupled to the substrate.

18. The method of claim 17, prior to disposing the plurality of connectors over the substrate, further comprising:
disposing a plurality of semiconductor device over the substrate, the plurality of semiconductor device laterally next to the first sub-package and the second sub-package;
applying an underfill over the substrate to fill gaps between the first sub-package and the substrate, between the first sub-package and the bridge die, the second sub-package and the substrate, and between the second sub-package and the bridge die; and
disposing a thermal dissipating element onto the substrate by an additional adhesive disposed therebetween.

19. The method of claim 17, prior to disposing the plurality of connectors over the substrate, further comprising:
disposing a plurality of semiconductor device over the substrate, the plurality of semiconductor device laterally next to the first sub-package and the second sub-package;
encapsulating the first sub-package, the second sub-package, the bridge die and the plurality of semiconductor devices in an insulating encapsulation; and
disposing a thermal dissipating element onto the insulating encapsulation by an additional adhesive disposed therebetween.

20. The method of claim 17, wherein mounting the first sub-package and the second sub-package to the substrate and the bridge die comprises:
mounting a first group of first connectors of the first sub-package to the substrate;
mounting a first group of second connectors of the first sub-package to the bridge die, wherein a height of the first group of first connectors is greater than a height of the first group of second connectors;
mounting a second group of first connectors of the second sub-package to the substrate; and
mounting a second group of second connectors of the second sub-package to the bridge die, wherein a height of the second group of first connectors is greater than a height of the second group of second connectors.
